(19) United States
(12) Patent Application Publication
(10) Pub. No.: US 2026/0068450 A1
(43) Pub. Date: Mar. 5, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Yuan YAO, Hefei (CN); Yiming XIAO, Hefei (CN); Manli CHEN, Hefei (CN); Chen XU, Hefei (CN); Xiujian ZHU, Hefei (CN)

(73) Assignees: Hefei Visionox Technology Co., Ltd., Hefei (CN); Visionox Technology Inc., Suzhou (CN)

(21) Appl. No.: 19/191,120

(22) Filed: Apr. 28, 2025

(30) Foreign Application Priority Data
Sep. 2, 2024 (CN) 202411223329.4
Jan. 22, 2025 (CN) 202510098608.0

(51) Int. Cl. H10K 59/126; H10K 59/131; H10K 59/80

(52) U.S. Cl. CPC H10K 59/126; H10K 59/131; H10K 59/873

(57) ABSTRACT

A display panel and a display device. The display panel includes a display area and a non-display area. The non-display area includes a first lead layer, a second lead layer, and a functional layer. The functional layer is arranged between the first lead layer and the second lead layer. The functional layer includes a function reuse layer. The function reuse layer includes a shielding layer and a first wire. The shielding layer includes a first sub-layer. The first wire is arranged in the same layer as the first sub-layer.

### CROSS REFERENCE TO RELATED APPLICATION

The present application claims priority to Chinese Patent Application No. 202411223329.4 filed on Sep. 2, 2024 and Chinese Patent Application No. 202510098608.0 filed on Jan. 22, 2025, both of which are incorporated herein by reference in their entireties.

### TECHNICAL FIELD

The present application relates to the technical field of display device, and in particular to a display panel and a display device.

### BACKGROUND

Planar display devices such as an organic light emitting diode (OLED) display panel and a display panel using a light emitting diode (LED) device are widely used in various consumer electronic products such as mobile phones, TVs, personal digital assistants, digital cameras, notebook computers, and desktop computers due to advantages such as high image quality, power saving, a thin body, and a wide range of applications, becoming the mainstream in display devices.

However, operational performance of existing OLED display products needs to be improved.

### SUMMARY

Embodiments of the present application provide a display panel and a display device, which can effectively shield signal crosstalk between different signal lines in a bezel area and also meet separate wiring requirements of different wires.

In a first aspect, a display panel is provided according to an embodiment of the present application, including a display area and a non-display area, the non-display area including a first lead layer, a second lead layer stacked along a first direction on one side of the first lead layer, and a functional layer arranged between the first lead layer and the second lead layer, the functional layer including a function reuse layer, the function reuse layer including a shielding layer and a first wire, the shielding layer including a first sub-layer, and the first wire being arranged in a same layer as the first sub-layer.

In a second aspect, a display panel is provided according to an embodiment of the present application, including a display area and a non-display area, the display panel including an array substrate and a second signal line layer stacked along a first direction, the array substrate including a first signal line layer, an interlayer insulating layer, and a wiring connection layer stacked along the first direction, and the interlayer insulating layer being arranged between the first signal line layer and the wiring connection layer; the wiring connection layer including: a first connection layer located in the display area; and a shielding layer and a first wire at least partially located in the non-display area, wherein an orthographic projection of the shielding layer on the interlayer insulating layer at least partially overlaps an orthographic projection of a first lead layer of the first signal line layer and a second lead layer of the second signal line layer on the interlayer insulating layer, the shielding layer includes a first sub-layer, the first sub-layer is arranged in the same layer as the first connection layer, and at least part of the first wire is arranged in the same layer as the first sub-layer.

In a third aspect, a display panel is provided according to an embodiment of the present application, including a display area and a non-display area, the non-display area including: a first lead layer; a second lead layer stacked along a first direction on one side of the first lead layer; and a power wire distribution layer arranged between the first lead layer and the second lead layer, the power wire distribution layer including a first distribution layer and a second distribution layer, and orthographic projections of the first distribution layer and the second distribution layer on the first lead layer at least partially overlapping.

In a fourth aspect, a display device is provided according to an embodiment of the present application, including the display panel in any one of the above embodiments.

According to the display panel provided in the present application, through the arrangement of the function reuse layer including the shielding layer and the first wire between the first lead layer and the second lead layer, signal crosstalk between the first lead layer and the second lead layer can be shielded while wiring separation is achieved.

### BRIEF DESCRIPTION OF THE DRAWINGS

Features, advantages, and technical effects of exemplary embodiments of the present application will be described below with reference to the accompanying drawings.

FIG. 1 shows a schematic top view of a partial structure of a display panel;

FIG. 2 shows a schematic diagram of a film stacking structure of the display panel shown in FIG. 1;

FIG. 3 shows a schematic diagram of a sectional structure taken along B-B′ in FIG. 1;

FIG. 4 shows a schematic diagram of a sectional structure taken along B-B′ in FIG. 1;

FIG. 5 shows a schematic diagram of a sectional structure taken along B-B′ in FIG. 1;

FIG. 6 shows a schematic diagram of a partial top view structure of FIG. 1;

FIG. 7 shows a schematic diagram of a partial top view structure of FIG. 1;

FIG. 8 shows a schematic diagram of a sectional structure taken along B-B′ in FIG. 1;

FIG. 9 shows a schematic diagram of a partial top view structure of FIG. 1;

FIG. 10 shows a schematic top view of a partial structure of a display panel;

FIG. 11 shows a schematic diagram of a sectional structure taken along A-A′ in FIG. 1;

FIG. 12 shows a schematic diagram of a sectional structure taken along B-B′ in FIG. 1;

FIG. 13 shows a schematic diagram of a film stacking structure of the display panel shown in FIG. 1;

FIG. 14 shows a schematic diagram of a sectional structure taken along A-A′ in FIG. 1;

FIG. 15 shows a schematic diagram of a sectional structure taken along B-B′ in FIG. 1;

FIG. 16 shows a schematic diagram of a film stacking structure of the display panel shown in FIG. 1;

FIG. 17 shows a schematic diagram of a sectional structure taken along A-A′ in FIG. 1;

FIG. 18 shows a schematic diagram of a sectional structure taken along B-B′ in FIG. 1;

FIG. 19 shows a schematic diagram of a film stacking structure of the display panel shown in FIG. 1;

FIG. 20 shows a schematic diagram of a sectional structure taken along A-A′ in FIG. 1;

FIG. 21 shows a schematic diagram of a sectional structure taken along B-B′ in FIG. 1;

FIG. 22 shows a schematic diagram of a film stacking structure of the display panel shown in FIG. 1;

FIG. 23 shows a schematic diagram of a sectional structure taken along A-A′ in FIG. 1;

FIG. 24 shows a schematic diagram of a sectional structure taken along B-B′ in FIG. 1;

FIG. 25 shows a schematic diagram of a film stacking structure of the display panel shown in FIG. 1;

FIG. 26 shows a schematic diagram of a sectional structure taken along A-A′ in FIG. 1;

FIG. 27 shows a schematic diagram of a sectional structure taken along B-B′ in FIG. 1;

FIG. 28 shows a schematic diagram of a film stacking structure of the display panel shown in FIG. 1

FIG. 29 shows a schematic diagram of a sectional structure taken along A-A′ in FIG. 1;

FIG. 30 shows a schematic diagram of a sectional structure taken along B-B′ in FIG. 1;

FIG. 31 shows a schematic diagram of a specific connection structure in an overlapping zone of a first film and a second film;

FIG. 32 shows a schematic diagram of a sectional structure taken along A-A′ in FIG. 1;

FIG. 33 shows a schematic diagram of a sectional structure taken along B-B′ in FIG. 1;

FIG. 34 shows a schematic diagram of a specific connection structure in an overlapping zone of a first film and a second film;

FIG. 35 shows a schematic diagram of a sectional structure taken along A-A′ in FIG. 1;

FIG. 36 shows a schematic diagram of a sectional structure taken along B-B′ in FIG. 1;

FIG. 37 shows a schematic diagram of another sectional structure taken along B-B′ in FIG. 1;

FIG. 38 shows a schematic diagram of another sectional structure taken along B-B′ in FIG. 1; and

FIG. 39 shows a schematic top view of part of a power wire distribution layer structure of the display panel.

In the drawings,
100: display panel;
11: display area; 12: non-display area; 13: functional layer; 14: power wire distribution layer;
121: dam area; 122: first area; 123: first zone; 124: second zone;
1221: first sub-area; 1222: second sub-area; 1223: straight edge area; 1224: arcuate corner area;
131: function reuse layer;
141: first distribution layer; 142: second distribution layer;
2: array substrate;
21: first signal line layer; 22: interlayer insulating layer; 23: wiring connection layer; 24: shielding layer; 25: first wire;
211: first signal unit layer; 212: first lead layer;
221: first via hole;
231: first connection layer; 232: second connection layer; 233: third connection layer;
241: first sub-layer; 2411: first aperture; 2412: first sub-section; 2413: first side; 2414: second side; 242: second sub-layer; 2421: third aperture; 243: third sub-layer; 244: first wire insulating layer; 245: second wire insulating layer;
251: first-layer power wire; 252: second-layer power wire; 253: third-layer power wire;
3: light-emitting layer;
31: light-emitting unit layer; 32: isolation structure layer; 33: substrate insulating layer; 34: electrode layer;
321: dummy pixel structure layer; 322: isolation material layer;
331: fourth aperture;
341: pixel electrode; 342: electrode shielding section; 3421: second aperture; 343: dummy electrode;
35: shielding assembly; 351: overlapping zone;
4: second signal line layer;
41: second signal unit layer; 42: second lead layer;
51: first film; 52: second film; 53: via hole; 54: first-film ventilation hole; 55: second-film ventilation hole;
531: first via hole; 532: second via hole; 533: third via hole;
541: first ventilation hole; 542: second ventilation hole; 551: third ventilation hole; 552: fourth ventilation hole;
61: first line end; 62: second line end; 63: third line end; 64: fourth line end; 65: first main section; 66: second main section;
d1: first distance; d2: second distance;
X: first direction; Y: second direction; Z: third direction;

In the drawings, same components are denoted by same reference numerals. The drawings are not drawn to actual scale.

### DETAILED DESCRIPTION

Features and exemplary embodiments in various aspects of the present application will be described in detail below. In the following detailed description, numerous specific details are set forth in order to provide a thorough understanding of the present application. However, it will be apparent to those skilled in the art that the present application can be implemented without some of these specific details. The following description of the embodiments is merely to provide a better understanding of the present application by illustrating the examples of the present application. In the drawings and the following description, at least part of well-known structures and technologies are not shown in order to avoid unnecessarily obscuring the present application. Further, for clarity, sizes of part of the structures may be exaggerated. Furthermore, the features, structures, or characteristics described below may be combined in any suitable manner in one or more embodiments.

It is to be noted that, herein, the relationship terms such as first and second are only used to distinguish one entity or operation from another entity or operation, but do not necessarily require or imply that there is such an actual relationship or order between these entities or operations. Moreover, the terms “include,” “comprise,” or any other variants thereof are intended to cover a non-exclusive inclusion, such that processes, methods, articles, or devices including a series of elements include not only those elements that have been listed, but also other elements that have not specifically been listed or the elements intrinsic to these processes, methods, articles, or devices. Without more limitations, elements limited by the wording “comprise(s)/include(s) a/an. . .” do not exclude additional identical elements in the processes, methods, articles, or devices including the listed elements.

The terms of orientation in the following description are all directions shown in the drawings and are not intended to limit specific structures of a display panel and a display device in the present application. In the description of the present application, it is to be further noted that unless otherwise specifically stated and limited, the terms “arrange” and “connect” should be understood in a broad sense, such as, a fixed connection, a detachable connection, or an integral connection; or a direct connection, or an indirect connection. For those of ordinary skill in the art, the specific meanings of the above terms in the present application may be understood depending on specific situations.

An OLED display is currently one of the common display solutions for electronic devices such as mobile phones, tablet computers, smart wearable devices, and large-screen display devices.

At present, in order to expand functions of the OLED display to enable the OLED display to be applied to a display device with a touch function as a main operating function, it is generally needed to combine the OLED display with a touch film to form a touch screen display panel 100 that integrates display and touch functions. The combination of the OLED display and the touch film includes various combinations such as embedded combination, laminating combination, and free-standing combination.

Regardless of how the OLED display and the touch film are combined, the display and the touch film are required to connect signal lines through a display bezel to a display driver IC (DDIC) outside the display panel 100. In the traditional OLED display panel 100 formed by evaporation using a fine metal mask (FMM) technology, the bezel is generally covered with a cathode material made of a transparent electrode material covering an entire surface, such as indium tin oxide (ITO).

The transparent electrode material covering the entire surface is arranged between the signal lines of the display and the touch film, which can shield signal crosstalk between the signal lines of the display and the touch film.

In the present application, the isolation structure is prepared to separately evaporate a pixel structure, the pixel density can be increased to optimize the display effect and implement personalized customization, and the transparent electrode material ITO covering the entire surface as a cathode is also avoided. The pixel structure uses a patterned cathode, in which there is no transparent electrode material covering the display bezel. When a touch screen is manufactured and the display is fit with the touch film, signal crosstalk between signal lines of a display film and the touch film is likely to occur at the bezel, affecting touch and display effects. Patent applications No. PCT/CN2023/134518, No. 202310759370.2, No. 202310740412.8, No. 202310707209.0, and No. 202311346196.5 describe related technical solutions of an isolation structure, and patent application No. 202311596673.3 describes related technical solutions of a shielding structure, the contents of which are incorporated herein by reference for reference. Details are not described in this embodiment.

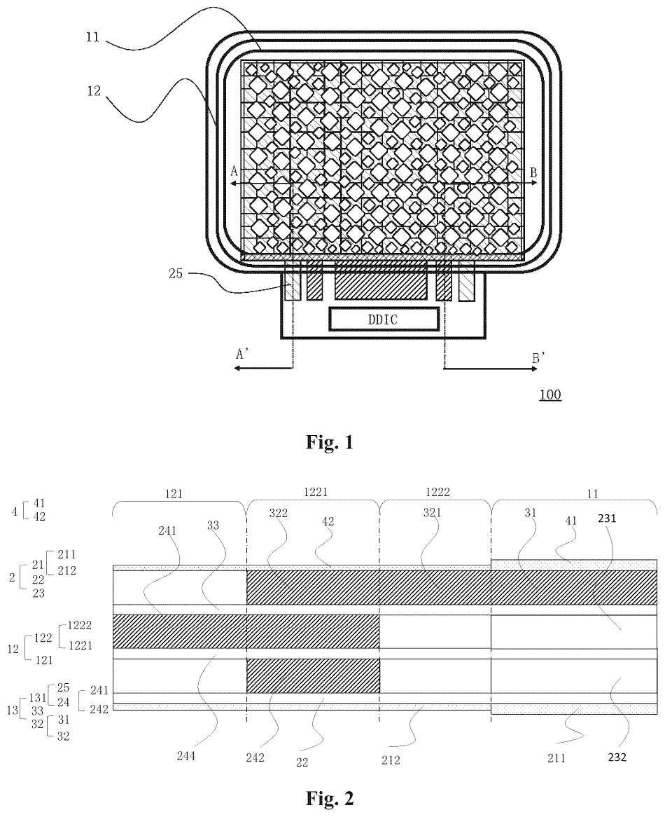

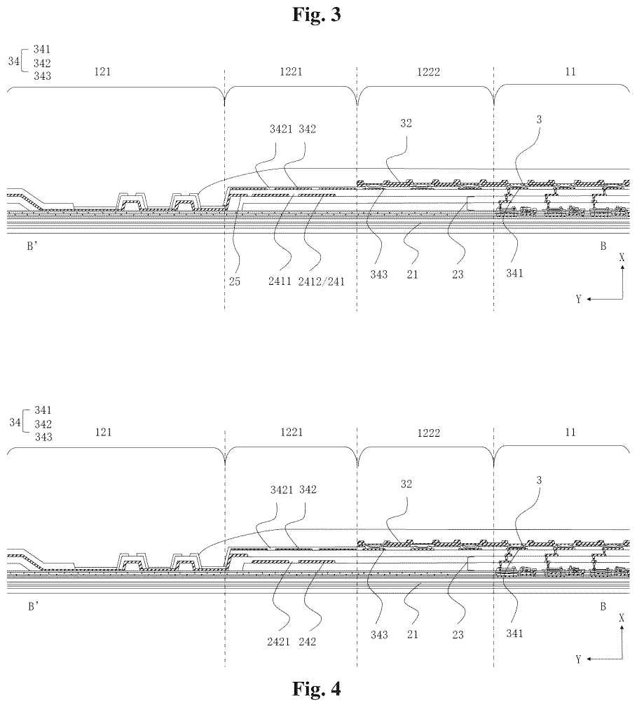

Referring to FIG. 1, FIG. 2, FIG. 3, and FIG. 4, an embodiment of the present application provides a display panel 100.

Although a main improvement zone of the display panel 100 shown in the figures is a lower bezel zone, which is illustrated as an example simply because it is convenient to illustrate the explanation and it is common technical arrangement in the art to arrange the following structure in the lower bezel zone, the present application is not limited to the lower bezel zone, which may also be arranged in any bezel zone of the display panel 100.

Referring to FIG. 1, the display panel 100 includes a display area 11 and a non-display area 12, and the non-display area 12 is arranged around the display area 11.

The non-display area 12 is arranged around the display area 11, and due to a requirement for various signal lines and wires externally connected to the DDIC from the display area 11, a first wire 25 is generally arranged to pass through the non-display area 12 from the middle or two sides of a film of the non-display area 12.

Referring to FIG. 2, FIG. 2 mainly shows a stacking relationship of the non-display area 12 and a corresponding same-layer relationship with the display area 11. The stacking relationship of the non-display area 12 will be described below.

The non-display area 12 includes a first lead layer 212, a second lead layer 42, and a functional layer 13.

The first lead layer 212 is arranged in the non-display area 12.

The first lead layer 212 is provided as a lead layer of a driving circuit in this embodiment only for convenience of illustration, which is not limited to the implementation of the lead layer of the driving circuit.

In the OLED display, the driving circuit is mainly responsible for controlling and driving pixel points of the OLED display to achieve display functions, including a variety of driving functions such as display signal processing, pixel point control, brightness and color control, and refresh rate control. The driving circuit needs to pass through the non-display area 12 located at the bezel, and the DDIC connects driving and control signals to the driving circuit through the first lead layer 212 located in the non-display area 12, so as to drive the entire display panel 100. The first lead layer 212 can lead out a signal interface of a drive and control driving circuit to facilitate butting with the DDIC.

The second lead layer 42 is stacked along a first direction X on one side of the first lead layer 212.

The second lead layer 42 is provided as a lead layer of a touch signal in this embodiment only for convenience of illustration, which is not limited to the implementation of the lead layer of the touch signal.

The touch signal mainly converts a touch operation of a user into an electrical signal and transmits the electrical signal to a processor or controller, such as the DDIC, including various signal recognition functions such as touch detection, positioning, multi-touch, and gesture recognition. The touch signal needs to pass through the non-display area 12 located at the bezel, and the DDIC connects, through the second lead layer 42 located in the non-display area 12, the touch signal to the DDIC for processing. The second lead layer 42 can lead out a structure that transmits the touch signal, to facilitate butting with the DDIC.

The functional layer 13 is arranged between the second lead layer 42 and the first lead layer 212 and includes a function reuse layer 131, a substrate insulating layer 33, and an isolation structure layer 32 stacked along the first direction X. The function reuse layer 131 is arranged adjacent to the first lead layer 212.

The substrate insulating layer 33 is arranged between the function reuse layer 131 and the isolation structure layer 32 and made of an organic or inorganic insulating material, and can insulate the function reuse layer 131 from the isolation structure layer 32, preventing problems such as crosstalk or accidental short connections.

The isolation structure layer 32 includes a part of an isolation pillar structure retained and extending into the non-display area 12 in order to enclose and form an isolation opening to manufacture a pixel unit in a subsequent process. The isolation structure layer 32 may be continuously arranged along a second direction Y and divided into a dummy pixel structure layer 321 and an isolation material layer 322.

For the dummy pixel structure layer 321 of the isolation structure layer 32, the pixel unit is still manufactured and retained, but is not electrically connected to the driving circuit, only a dummy pixel structure is retained. The dummy pixel structure retained is provided at least a pixel cathode overlapping the isolation structure and a pixel anode with at least two metal layers and also provided with a pixel structure formed by evaporation between isolation structures, so that a better shielding effect can be provided between the first lead layer 212 and the second lead layer 42.

For the isolation material layer 322 of the isolation structure layer 32, only a material film for manufacturing the isolation structure is laid, but the isolation structure is not manufactured, and no pixel structure is formed by evaporation, so as to reserve space for overlapping between wiring and the isolation structure layer 32.

The function reuse layer 131 includes a shielding layer 24 and a first wire 25, the shielding layer 24 includes a second sub-layer 242 and a first sub-layer 241 stacked along the first direction X, and the first wire 25 is arranged in the same layer as at least one of the first sub-layer 241 and the second sub-layer 242. The function reuse layer 131 can pre-distribute space for wires that need to be distributed in the non-display area 12 and further improve the shielding effect through the arrangement of the shielding layer 24.

The non-display area 12 is divided along the second direction Y sequentially into a first area 122 and a dam area 121 continuously arranged, and the first area 122 can be divided along the second direction Y sequentially into a first sub-area 1221 and a second sub-area 1222 continuously arranged.

The isolation structure layer 32 extends to the first area 122. The dummy pixel structure layer 321 of the isolation structure layer 32 correspondingly extends to the first sub-area 1221 of the first area 122, and the isolation material layer 322 of the isolation structure layer 32 correspondingly extends to the second sub-area 1222 of the first area 122.

The first sub-layer 241 extends to the second sub-area 1222 and the dam area 121, and the second sub-layer 242 extends to the second sub-area 1222.

An orthographic projection of the second lead layer 42 and the first lead layer 212 in the first area 122 at least partially overlaps an orthographic projection of the isolation structure layer 32 and the first sub-layer 241 in the first area 122, thereby providing shielding in the first area 122 by the isolation structure layer 32 and the first sub-layer 241.

An orthographic projection of the second lead layer 42 and the first lead layer 212 in the dam area 121 at least partially overlaps an orthographic projection of the first sub-layer 241 in the dam area 121, thereby providing shielding in the dam area 121 by the first sub-layer 241.

Specifically, an orthographic projection of the second lead layer 42 and the first lead layer 212 in the first sub-area 1221 at least partially overlaps an orthographic projection of the dummy pixel structure layer 321 in the first sub-area 1221, thereby providing shielding in the first sub-area 1221 by the dummy pixel structure layer 321.

An orthographic projection of the second lead layer 42 and the first lead layer 212 in the second sub-area 1222 at least partially overlaps an orthographic projection of the isolation material layer 322, the first sub-layer 241, and the second sub-layer 242 in the second sub-area 1222, thereby providing shielding in the second sub-area 1222 by the isolation material layer 322, the first sub-layer 241, and the second sub-layer 242.

An orthographic projection of the second lead layer 42 and the first lead layer 212 in the dam area 121 at least partially overlaps an orthographic projection of the first sub-layer 241 in the dam area, thereby providing shielding in the dam area 121 by the first sub-layer 241.

The isolation structure layer 32 extends to the first area 122, so that an isolation material for manufacturing the pixel structure can be extended to the non-display area 12 to produce a shielding effect, and effective overlapping with the structure of the display area 11 can be ensured.

The first sub-layer 241 extends to the second sub-area 1222 and the dam area 121, so that a shielding effect can be produced by the first sub-layer 241 and various power lines and signal lines in the function reuse layer 131 can be led out of the non-display area 12 through the first sub-layer 241.

The second sub-layer 242 extends to the second sub-area 1222, so that the shielding effect of the second sub-area 1222 can be further improved.

Through such arrangement, the isolation structure layer 32 and the function reuse layer 131 are stacked on each other to completely cover the non-display area 12, so that signal crosstalk between the first lead layer 212 and the second lead layer 42 can be effectively shielded in the non-display area 12 at the bezel. Furthermore, the isolation structure layer 32, the first sub-layer 241, and the second sub-layer 242 are provided in the second sub-area 1222 to achieve three-layer shielding, so that the shielding effect is better.

Referring to FIG. 2 and FIG. 3, in which FIG. 3 shows a schematic diagram of a sectional structure taken along B-B′ in FIG. 1.

As shown in FIG. 2 and FIG. 3, in some optional embodiments, the light-emitting layer 3 further includes an electrode layer 34 located between the array substrate 2 and the light-emitting unit layer 31, the electrode layer 34 includes pixel electrodes 341 located in the display area 11 and electrode shielding sections 342 at least partially located in the non-display area 12, and an orthographic projection of the electrode shielding section 342 on the interlayer insulating layer 22 at least partially overlaps the orthographic projection of the first lead layer 212 of the first signal line layer 21 and the second lead layer 42 of the second signal line layer 4 on the interlayer insulating layer 22.

Optionally, a portion of the pixel electrodes 341 are exposed from the isolation openings to serve as the light-emitting electrodes of the pixel units.

Optionally, the electrode layer 34 further includes dummy electrodes 343 located in the second sub-area 1222, and a portion of the dummy electrodes 343 are exposed from the isolation openings in the second sub-area 1222. The dummy electrodes 343 and the isolation structure layer 32 in the second sub-area 1222 can collectively provide better shielding effect between the first lead layer 212 and the second lead layer 42. Optionally, the dummy electrode 343 is provided with a dummy unit and a cathode on a side of the dummy electrode 343 away from the interlayer insulating layer 22, and the dummy unit is arranged in the same layer as the light-emitting unit. The dummy electrode 343 is not electrically connected to a pixel circuit.

Optionally, the electrode shielding section 342 is located at least in the first sub-area 1221, for example, the electrode shielding section 342 may be located in the first sub-area 1221, or the electrode shielding section 342 is located in the first sub-area 1221 and the second sub-area 1222.

In these optional embodiments, the pixel electrodes 341 of the electrode layer 34 are located in the display area 11 to drive the pixel units in the display area 11 to emit light. The orthographic projection of the electrode shielding section 342 on the interlayer insulating layer 22 at least partially overlaps the orthographic projection of the first lead layer 212 of the first signal line layer 21 and the second lead layer 42 of the second signal line layer 4 on the interlayer insulating layer 22, i.e., the first sub-area 1221 is provided with the electrode shielding section 342 and the first sub-layer 241 or the second sub-layer 242, so as to achieve two-layer shielding, and thus the shielding effect is better. The pixel electrode 341 is provided with a light-emitting unit and a cathode on a side of the pixel electrode 341 away from the interlayer insulating layer 22. The pixel electrode 341 is electrically connected to the pixel circuit to drive the light-emitting unit to emit light.

In some optional embodiments, the first sub-layer 241 is further provided with a first aperture 2411, the electrode shielding section 342 is further provided with a second aperture 3421, and an orthographic projection of the first aperture 2411 on the interlayer insulating layer 22 is located within the orthographic projection of the electrode shielding section 342 on the interlayer insulating layer 22.

Optionally, part of the first sub-layer 241 is located in the first sub-area 1221.

In these optional embodiments, the first sub-layer 241 is provided with the first aperture 2411, so that water vapor on a side of the first sub-layer 241 away from the isolation structure layer 32 can be transmitted through the first aperture 2411, and the electrode shielding section 342 is provided with the second aperture 3421, so that water vapor on a side of the electrode shielding section 342 away from the isolation structure layer 32 can be transmitted through the second aperture 3421. The orthographic projection of the first aperture 2411 on the interlayer insulating layer 22 is located within the orthographic projection of the electrode shielding section 342 on the interlayer insulating layer 22, i.e., the area in which the first aperture 2411 is located is covered by the electrode shielding section 342, so that the first sub-layer 241 is provided with the electrode shielding section 342 in the area in which the first aperture 2411 is located which has no shielding effect, so as to provide shielding effect for the area in which the first aperture 2411 is located, and improve the shielding capacity of the electrode shielding section 342 and the first sub-layer 241 within the first sub-area 1221.

In some optional embodiments, an orthographic projection of the second aperture 3421 on the interlayer insulating layer 22 is located within an orthographic projection of the first sub-layer 241 on the interlayer insulating layer 22.

In these optional embodiments, the area in which the second aperture 3421 is located is covered by the first sub-layer 241, so that the electrode shielding section 342 is provided with the first sub-layer 241 in the area in which the second aperture 3421 is located which has no shielding effect, so as to provide shielding effect for the area in which the second aperture 3421 is located, and improve the shielding capacity of the electrode shielding section 342 and the first sub-layer 241 within the first sub-area 1221.

Optionally, the orthographic projection of the first aperture 2411 on the interlayer insulating layer 22 is located within the orthographic projection of the electrode shielding section 342 on the interlayer insulating layer 22, and the orthographic projection of the second aperture 3421 on the interlayer insulating layer 22 is located within the orthographic projection of the first sub-layer 241 on the interlayer insulating layer 22, and thus the electrode shielding section 342 and the first sub-layer 241 can provide whole-surface shielding within the first sub-area 1221, so as to further improve the shielding effect within the first sub-area 1221.

Referring to FIG. 2 and FIG. 4, in which FIG. 4 shows a schematic diagram of a sectional structure taken along B-B′ in FIG. 1.

As shown in FIG. 2 and FIG. 4, in some optional embodiments, the second sub-layer 242 is further provided with a third aperture 2421, and an orthographic projection of the third aperture 2421 on the interlayer insulating layer 22 is located within the orthographic projection of the electrode shielding section 342 on the interlayer insulating layer 22.

Optionally, a portion of the second sub-layer 242 is located in the first sub-area 1221.

In these optional embodiments, the second sub-layer 242 is provided with the third aperture 2421, so that water vapor on a side of the second sub-layer 242 away from the isolation structure layer 32 can be transmitted through the third aperture 2421. The orthographic projection of the third aperture 2421 on the interlayer insulating layer 22 is located within the orthographic projection of the electrode shielding section 342 on the interlayer insulating layer 22, i.e., the area in which the third aperture 2421 is located is covered by the electrode shielding section 342, so that the second sub-layer 242 is provided with the electrode shielding section 342 in the area in which the third aperture 2421 which has no shielding effect, so as to provide shielding effect for the area in which the third aperture 2421 is located, and improve the shielding capacity of the electrode shielding section 342 and the second sub-layer 242 within the first sub-area 1221.

In some optional embodiments, the orthographic projection of the second aperture 3421 on the interlayer insulating layer 22 is located within an orthographic projection of the second sub-layer 242 on the interlayer insulating layer 22.

In these optional embodiments, the area in which the second aperture 3421 is located is covered by the second sub-layer 242, so that the electrode shielding section 342 is provided with the second sub-layer 242 in the area in which the second aperture 3421 is located which has no shielding effect, so as to provide shielding effect for the area in which the second aperture 3421 is located, and improve the shielding capacity of the electrode shielding section 342 and the second sub-layer 242 within the first sub-area 1221.

Optionally, the orthographic projection of the third aperture 2421 on the interlayer insulating layer 22 is located within the orthographic projection of the electrode shielding section 342 on the interlayer insulating layer 22, and the orthographic projection of the second aperture 3421 on the interlayer insulating layer 22 is located within the orthographic projection of the second sub-layer 242 on the interlayer insulating layer 22, and thus the electrode shielding section 342 and the second sub-layer 242 can provide whole-surface shielding within the first sub-area 1221, so as to further improve the shielding effect within the first sub-area 1221.

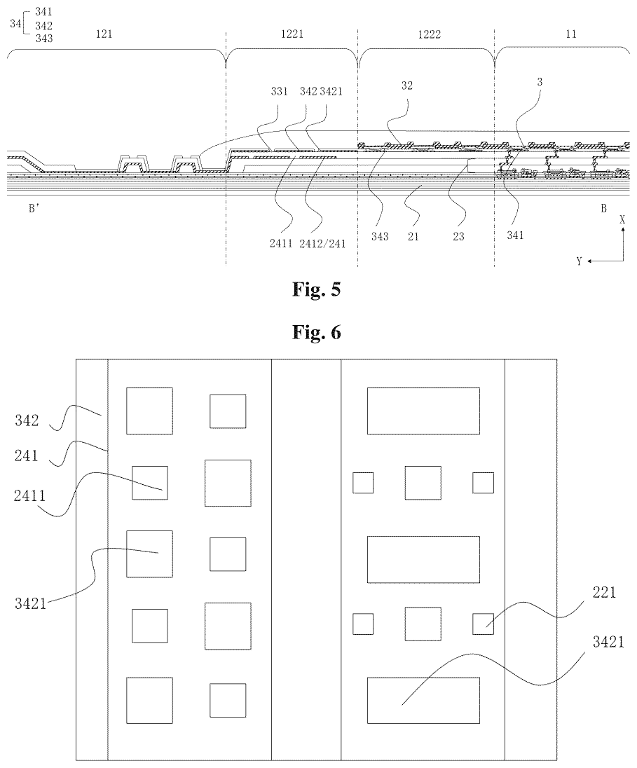

Referring to FIG. 2 and FIG. 5, in which FIG. 5 shows a schematic diagram of a sectional structure taken along B-B′ in FIG. 1.

As shown in FIG. 2 and FIG. 5, optionally, the substrate insulating layer 33 is provided with a fourth aperture 331 located in the first sub-area 1221, and the fourth aperture 331 is connected to the second aperture 3421 to be combined to form a through aperture, so as to achieve ventilation effect.

As shown in FIG. 3, optionally, the first sub-layer 241 is insulated from the first wire 25, and the first sub-layer 241 and the first wire 25 are related to signals independent of each other, i.e., the first sub-layer 241 located in the first sub-area 1221 does not transmit the power signal of the first wire 25 and merely provides signal shielding effect, so as to avoid interference with the signal transmission of the first wire 25 when the signal of the first sub-layer 241 is shielded.

In some optional embodiments, the first sub-layer 241 is electrically connected to the electrode layer 34. For example, the first sub-layer 241 is electrically connected to the electrode shielding section 342.

Optionally, the electrode shielding section 342 is electrically connected to the isolation structure layer 32, or the electrode shielding section 342 has the same electrical signal as the isolation structure layer 32.

In these optional embodiments, the first sub-layer 241 and the electrode shielding section 342 are electrically connected, so that the first sub-layer 241 and the electrode shielding section 342 have the same electrical signal which is the same as the signal transmitted by the isolation structure layer 32, i.e., the first sub-layer 241 and the electrode shielding section 342 have a stabilized potential, so as to provide better shielding effect between the first lead layer 212 and the second lead layer 42.

Referring to FIGS. 2, 3, and 6, in which FIG. 6 shows a schematic diagram of a partial top view structure of FIG. 1.

As shown in FIGS. 2, 3, and 6, optionally, the substrate insulating layer 33 includes a planarization layer located between the electrode shielding section 342 and the first sub-layer 241, the planarization layer is provided with a first via hole 221, and the electrode shielding section 342 and the first sub-layer 241 are electrically connected through the first via hole.

Optionally, an orthographic projection of the first via hole 221 on the interlayer insulating layer 22 is spaced apart from both the orthographic projection of the first aperture 2411 on the interlayer insulating layer 22 and the orthographic projection of the second aperture 3421 on the interlayer insulating layer 22.

In some optional embodiments, the first sub-layer 241 includes a plurality of first sub-sections 2412 arranged at intervals, and the first aperture 2411 is located in the first sub-sections 2412.

Optionally, the orthographic projection of the second aperture 3421 on the interlayer insulating layer 22 is located within an orthographic projection of the first sub-section 2412 on the interlayer insulating layer 22.

In these optional embodiments, the plurality of first sub-sections 2412 are spaced apart from each other to form gaps, so as to reserve sufficient space to facilitate the wiring of the first wire 25 within the first sub-area 1221. The area in which the second aperture 3421 is located is covered by the first sub-section 2412, so that the electrode shielding section 342 is provided with the first sub-section 2412 in the area in which the second aperture 3421 is located which has no shielding effect, so as to provide shielding effect for the area in which the second aperture 3421 is located, and improve the shielding capability of the electrode shielding section 342 and the first sub-section 2412 within the first sub-area 1221.

In some optional embodiments, a minimum distance between an edge of the orthographic projection of the second aperture 3421 on the interlayer insulating layer 22 and an edge of an orthographic projection of a corresponding first sub-section 2412 on the interlayer insulating layer 22 is greater than or equal to 5μm. For example, the minimum distance between the edge of the orthographic projection of the second aperture 3421 on the interlayer insulating layer 22 and the edge of the orthographic projection of the corresponding first sub-section 2412 on the interlayer insulating layer 22 is 5μm, 6μm, 8μm, 10μm, and the like.

In these optional embodiments, the width of an overlapping portion between the orthographic projection of the second aperture 3421 on the interlayer insulating layer 22 and the orthographic projection of the corresponding first sub-section 2412 on the interlayer insulating layer 22 is greater than or equal to 5 μm, which can avoid the case in which the width of the overlapping portion is too small, the signal of the second lead layer 42 is difficult to be completely shielded by the first sub-section 2412 after passing through the second aperture 3421, and thus there is still signal crosstalk between the first lead layer 212 and the second lead layer 42. The first wire 25 includes, but is not limited to, a GIP wire.

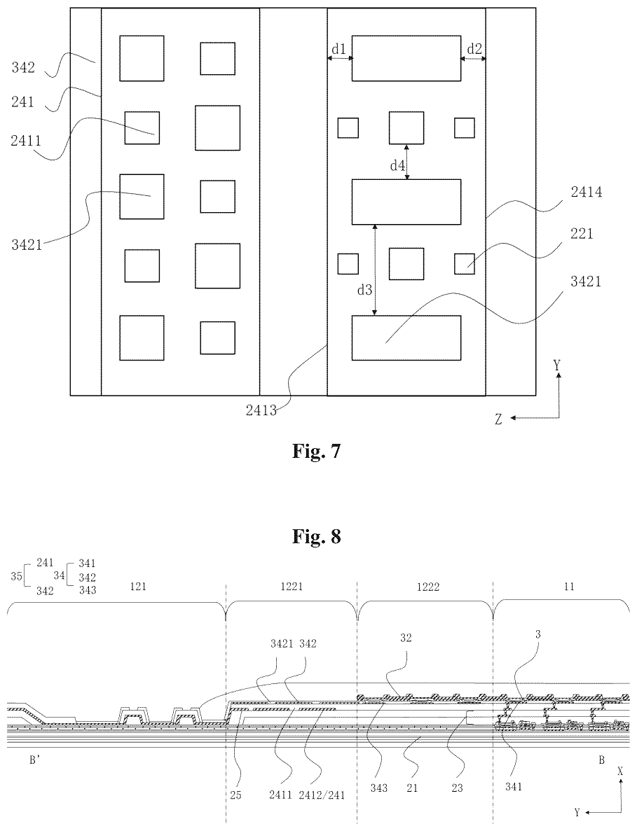

Referring to FIG. 2 and FIG. 7, in which FIG. 7 shows a schematic diagram of a partial top view structure of FIG. 1.

As shown in FIG. 2 and FIG. 7, optionally, an edge of the orthographic projection of the first sub-section 2412 on the interlayer insulating layer 22 has a first side 2413 and a second side 2414 opposite to each other, a distance between the edge of the orthographic projection of the second aperture 3421 on the interlayer insulating layer 22 and the first side 2413 is a first distance d1, a distance between the edge of the orthographic projection of the second aperture 3421 on the interlayer insulating layer 22 and the second side 2414 is a second distance d2, and the first distance d1 is equal to the second distance d2, so that the shielding capacity of the first sub-section 2412 is evenly distributed, and the shielding effect is improved.

In some optional embodiments, the first distance d1 is greater than or equal to 5 m. For example, the first distance d1 is 5 μm, 6 μm, 8 μm, 10 μm, and the like.

In these optional embodiments, the first distance d1 is greater than or equal to 5 μm, which can avoid the case in which the width of the overlapping portion is too small, the signal of the second lead layer 42 is difficult to be completely shielded by the first sub-section 2412 after passing through the second aperture 3421, and thus there is still signal crosstalk between the first lead layer 212 and the second lead layer 42.

In some optional embodiments, the second distance d2 is greater than or equal to 5 μm. For example, the second distance d2 is 5 μm, 6 μm, 8 μm, 10 μm, and the like.

In these optional embodiments, the second distance d2 is greater than or equal to 5 μm, which can avoid the case in which the width of the overlapping portion is too small, the signal of the second lead layer 42 is difficult to be completely shielded by the first sub-section 2412 after passing through the second aperture 3421, and thus there is still signal crosstalk between the first lead layer 212 and the second lead layer 42.

In some optional embodiments, a distance d3 between adjacent second apertures 3421 is less than or equal to 80 μm. For example, the distance between adjacent second apertures 3421 is 50 μm, 60 μm, 70 μm, 80 μm, and the like.

In these optional embodiments, the distance between adjacent second apertures 3421 is less than or equal to 80 μm, which can avoid the case in which the distance between adjacent second apertures 3421 is too large, the area of the second aperture 3421 is too small and the area of the electrode shielding section 342 is too large, and thus the risk of entire layer warping or film peeling of the electrode shielding section 342 increases.

Optionally, the first sub-section 2412 extends along the second direction Y, and the first aperture 2411 and the second aperture 3421 are staggered along the second direction Y.

In some optional embodiments, one second aperture 3421 is arranged between two first apertures 2411 adjacent along the second direction Y, which means that the orthographic projection of one second aperture 3421 on the interlayer insulating layer 22 is located between the orthographic projections of two first apertures 2411 adjacent along the second direction Y on the interlayer insulating layer 22.

In these optional embodiments, only one second aperture 3421 is arranged between two first apertures 2411, and in the limited space between the two first apertures 2411, the area of the one second aperture 3421 can be set as large as possible, so as to maximize the second aperture 3421, which can avoid the case in which the area of the second aperture 3421 is too small and the area of the electrode shielding section 342 is too large, and thus the risk of entire layer warping or film peeling of the electrode shielding section 342 increases.

In some optional embodiments, a distance d4 between the second aperture 3421 and the adjacent first aperture 2411 is greater than or equal to 5 μm. For example, the distance between the second aperture 3421 and the adjacent first aperture 2411 is 5 μm, 6 μm, 8 μm, 10 μm, and the like. The distance between the second aperture 3421 and the adjacent first aperture 2411 refers to a distance between the orthographic projection of the second aperture 3421 on the interlayer insulating layer 22 and the orthographic projection of the adjacent first aperture 2411 on the interlayer insulating layer 22.

In these optional embodiments, the distance between the second aperture 3421 and the adjacent first aperture 2411 is greater than or equal to 5 μm, which can avoid the case in which between the second aperture 3421 and the first aperture 2411, the width of the overlapping portion between the electrode shielding section 342 and the first sub-section 2412 is too small, the signal of the second lead layer 42 is difficult to be completely shielded by the first sub-section 2412 after passing through the second aperture 3421, and thus there is still signal crosstalk between the first lead layer 212 and the second lead layer 42.

In some optional embodiments, the first area 122 includes a first sub-area 1221 and a second sub-area 1222, the first sub-area 1221 is located on a side of the second sub-area 1222 away from the display area 11, the display panel 100 includes a shielding assembly 35, the shielding assembly 35 includes the first sub-layer 241 and the electrode shielding section 342, and an orthographic projection of the first sub-area 1221 on the interlayer insulating layer 22 is located within an orthographic projection of the shielding assembly 35 on the interlayer insulating layer 22.

In these optional embodiments, the first sub-area 1221 is completely covered by the shielding assembly 35 to improve the shielding effect of the first sub-area 1221, so as to further avoid signal crosstalk between the first lead layer 212 and the second lead layer 42 in the first sub-area 1221.

Referring to FIG. 8, which shows a schematic diagram of a sectional structure taken along B-B′ in FIG. 1.

As shown in FIG. 8, in some optional embodiments, the isolation structure layer 32 is located in the display area 11 and the second sub-area 1222, and an orthographic projection of the isolation structure layer 32 on the interlayer insulating layer 22 and the orthographic projection of the electrode shielding section 342 on the interlayer insulating layer 22 overlaps in the second sub-area 1222.

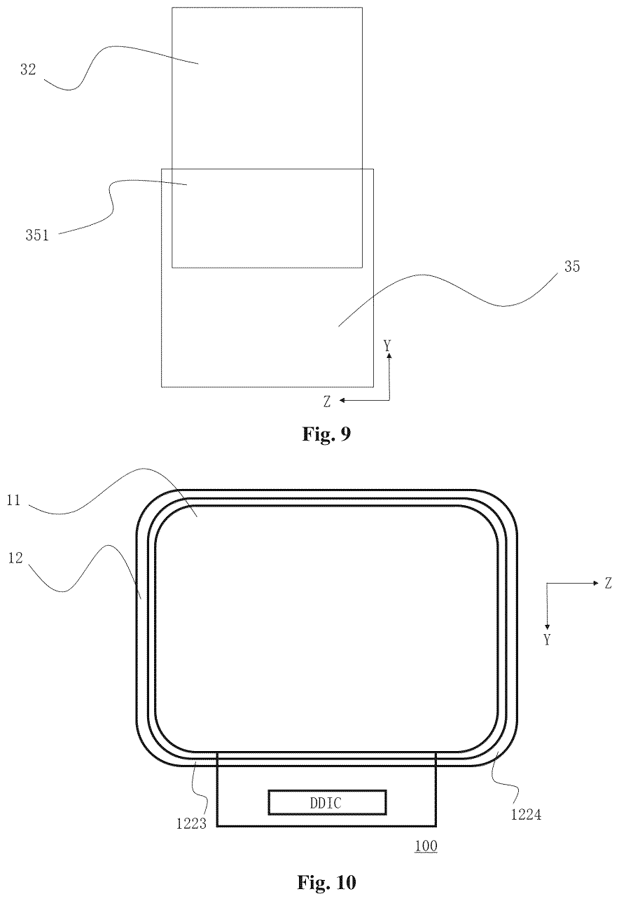

Referring to FIGS. 2, 8, and 9, in which FIG. 9 shows a schematic diagram of a partial top view structure of FIG. 1.

As shown in FIGS. 2, 8, and 9, in these optional embodiments, the shielding assembly 35 overlaps the isolation structure layer 32, so that the shielding areas of the shielding assembly 35 and the isolation structure layer 32 are continuous, which avoids crosstalk area between the shielding assembly 35 and the isolation structure layer 32, and further improves the shielding effect within the first sub-area 1221 and the second sub-area 1222.

In some optional embodiments, the orthographic projection of the shielding assembly 35 on the interlayer insulating layer 22 and the orthographic projection of the isolation structure layer 32 on the interlayer insulating layer 22 overlaps to form an overlapping zone 351, and a minimum width of the overlapping zone 351 along a direction from the non-display area 12 to the display area 11 is greater than or equal to 5 μm. For example, the minimum width of the overlapping zone 351 along the direction from the non-display area 12 to the display area 11 is 5 μm, 6 μm, 8 μm, 10 μm, and the like.

In these optional embodiments, the minimum width of the overlapping zone 351 along the direction from the non-display area 12 to the display area 11 is greater than or equal to 5 μm, which can avoid the case in which the width of the overlapping zone 351 is too small and the shielding effect of the overlapping zone 351 is poor, perfect shielding cannot be achieved in the overlapping zone 351, and thus there is still signal crosstalk between the first lead layer 212 and the second lead layer 42 in the overlapping zone 351.

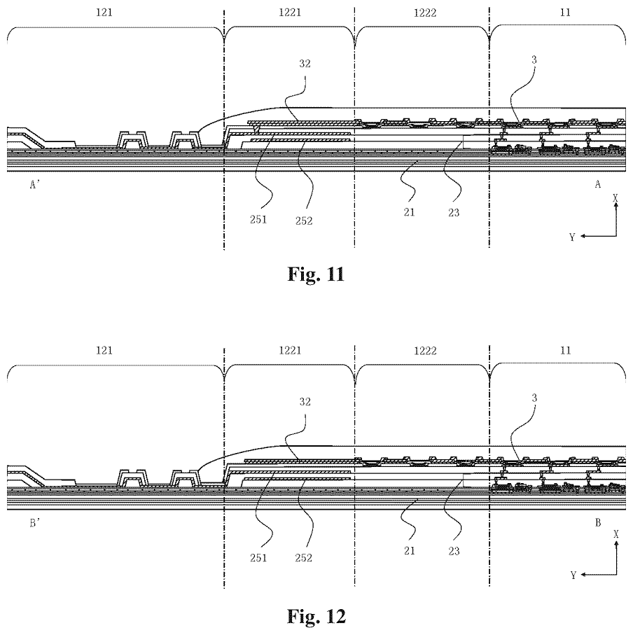

Referring to FIGS. 2 to 10, in which FIG. 10 shows a schematic top view of a partial structure of a display panel.

As shown in FIGS. 2 to 10, in some optional embodiments, the non-display area 12 includes a straight edge area 1223 and an arcuate corner area 1224 located on two sides of the straight edge area 1223 along a third direction Z, the straight edge area 1223 is located on one side of the display area 11 along the second direction Y, and the shielding assembly 35 is located in the straight edge area 1223 and the arcuate corner area 1224.

In these optional embodiments, the shielding assembly 35 is arranged in both the straight edge area 1223 and the arcuate corner area 1224, so that both the straight edge area 1223 and the arcuate corner area 1224 have better shielding effect.

Optionally, the minimum width of the overlapping zone 351 formed by the orthographic projection of the shielding assembly 35 within the straight edge area 1223 on the interlayer insulating layer 22 overlapping the orthographic projection of the isolation structure layer 32 on the interlayer insulating layer 22 is greater than or equal to 5μm.

Optionally, the minimum width of the overlapping zone 351 formed by the orthographic projection of the shielding assembly 35 within the arcuate corner area 1224 on the interlayer insulating layer 22 overlapping the orthographic projection of the isolation structure layer 32 on the interlayer insulating layer 22 is greater than or equal to 5μm.

In some optional embodiments, the light-emitting unit layer 31 further includes dummy units located in the non-display area 12, the dummy units are located on a side of dummy electrodes away from the interlayer insulating layer 22, and a number of the dummy units within the arcuate corner area 1224 is greater than a number of the dummy units in the straight edge area 1223.

In these optional embodiments, the width of the arcuate corner area 1224 is greater than the width of the straight edge area 1223, and in order that the minimum width of the overlapping zone 351 formed by the orthographic projection of the shielding assembly 35 within the arcuate corner area 1224 on the interlayer insulating layer 22 overlapping the orthographic projection of the isolation structure layer 32 on the interlayer insulating layer 22 is greater than or equal to 5μm, more dummy units are arranged in the arcuate corner area 1224, and the isolation structure layer 32 can extend further towards the arcuate corner area 1224, so as to further increase the overlapping width between the isolation structure layer 32 and the shielding assembly 35.

A corresponding relationship between films of the non-display area 12 and the display area 11 will be described below.

The display area 11 is a main functional area of the display panel 100 for displaying content, and can emit light and display different texts, images, and videos through different brightness and color adjustments.

The display area 11 includes a first signal unit layer 211, an interlayer insulating layer 22, a second connection layer 232, a first wire insulating layer 244, a first connection layer 231, a light-emitting unit layer 31, and a second signal unit layer 41 stacked along the first direction X.

The first lead layer 212 located in the non-display area 12 is arranged in the same layer as the first signal unit layer 211 located in the display area, and the first lead layer 212 and the first signal unit layer 211 collectively form the first signal line layer 21.

The second sub-layer 242 located in the non-display area 12 is arranged in the same layer as the second connection layer 232 located in the display area 11, the first sub-layer 241 located in the non-display area 12 is arranged in the same layer as the first connection layer 231 located in the display area 11, and the first sub-layer 241, the second sub-layer 242, the first connection layer 231, the second connection layer 232, the first wire insulating layer 244, and the first wire 25 collectively form the wiring connection layer 23.

The first signal line layer 21, the wiring connection layer 23, and the interlayer insulating layer 22 are stacked along the first direction X to form the array substrate 2 collectively. The interlayer insulating layer 22 is arranged between the first signal line layer 21 and the wiring connection layer 23.

For the isolation structure layer 32 located in the non-display area 12 and the light-emitting unit layer 31 located in the display area 11, the light-emitting unit layer 31 includes a plurality of light-emitting units, the isolation structure layer 32 encloses and forms a plurality of isolation openings, the light-emitting units are exposed from the isolation openings, the substrate insulating layer is arranged between the isolation structure layer 32 and the array substrate 2, and the substrate insulating layer 33, the isolation structure layer 32, and the light-emitting unit layer 31 collectively form the light-emitting layer 3.

The second lead layer 42 located in the non-display area 12 is arranged in the same layer as the second signal unit layer 41 located in the display area, and the second lead layer 42 and the second signal unit layer 41 collectively form the second signal line layer 4.

Through such arrangement, the films in the display area 11 are in one-to-one correspondence to the films in the non-display area 12 to facilitate subsequent wire overlapping.

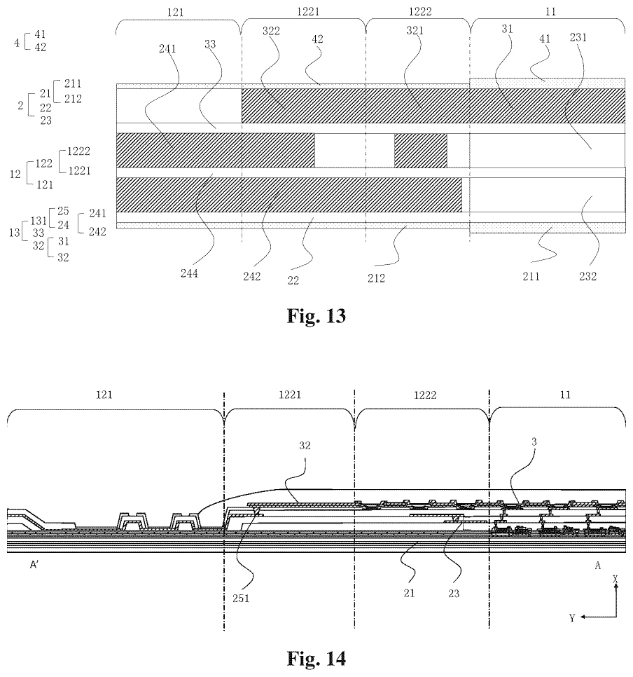

Referring to FIG. 11 and FIG. 12, which mainly show an overlapping relationship of power wires in the non-display area 12. The first wire 25 includes a first-layer power wire 251 arranged in the same layer as the first sub-layer 241 and a second-layer power wire 252 arranged in a same layer as the second sub-layer 242. Orthographic projections of one part of the first-layer power wire 251 and the isolation structure layer 32 on the interlayer insulating layer 22 partially overlap, and the part of the first-layer power wire 251 is electrically connected with the isolation structure layer 32.

Orthographic projections of the second-layer power wire 252 and the first-layer power wire 251 on the interlayer insulating layer 22 partially overlap.

The first wire 25 includes a first power line and a second power line. The first power line is the other part of the first-layer power wire 251, and the second power line is the part of the first-layer power wire 251 and the isolation structure layer 32 in which the orthographic projections of the part of the first-layer power wire 251 and the isolation structure layer 32 on the interlayer insulating layer 22 partially overlap, and the part of the first-layer power wire 251 is electrically connected with the isolation structure layer 32.

In some embodiments, the first power line is an Electroluminscent Voltage Drain (ELVDD) power line, the second power line is an Electroluminscent Voltage Source (ELVSS) power line, and the ELVSS power line and the ELVDD power line are lines that supply power to the light-emitting layer 3 of the display panel 100.

Through such arrangement, the second-layer power wire 252 partially overlaps the first-layer power wire 251, which can improve the shielding effect.

The display panel 100 provided in the embodiments of the present application can effectively shield signal crosstalk between the first lead layer 212 and the second lead layer 42.

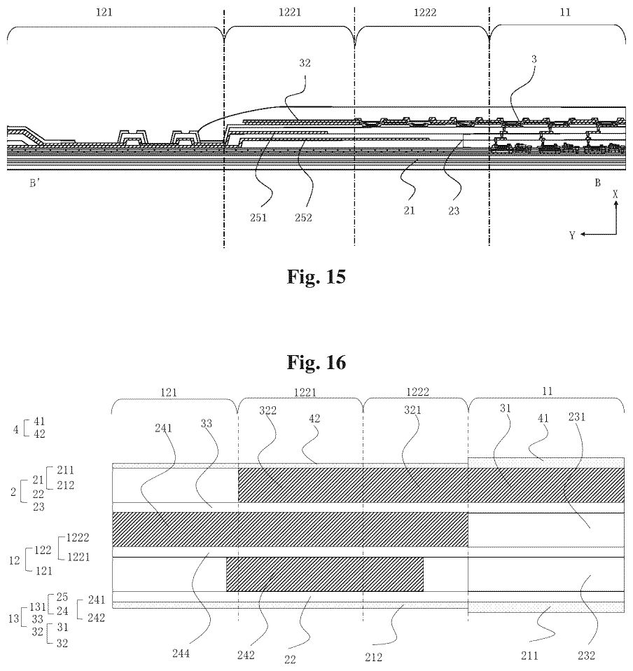

Referring to FIG. 13, FIG. 14, and FIG. 15, another embodiment of the present application provides a display panel 100.

FIG. 13 mainly shows a stacking relationship of the non-display area 12 and a corresponding same-layer relationship with the display area. The stacking relationship of the non-display area 12 will be described below.

The non-display area 12 includes a first lead layer 212, a second lead layer 42, and a functional layer 13, for which the functions and arrangement manners have been illustrated in the above embodiments, so details are not described herein.

The first sub-layer 241 extends to the second sub-area 1222 and the dam area 121, and the second sub-layer 242 extends to the first sub-area 1221, the second sub-area 1222, and the dam area 121.

An orthographic projection of the first lead layer 212 and the second lead layer 42 in the first sub-area 1221 at least partially overlaps an orthographic projection of the dummy pixel structure layer 321 and the second sub-layer 242 in the first sub-area 1221, thereby providing shielding in the first sub-area 1221 by the dummy pixel structure layer 321 and the second sub-layer 242.

An orthographic projection of the first lead layer 212 and the second lead layer 42 in the second sub-area 1222 at least partially overlaps an orthographic projection of the isolation material layer 322, the first sub-layer 241, and the second sub-layer 242 in the second sub-area 122, thereby providing shielding in the second sub-area 1222 by the isolation material layer 322, the first sub-layer 241, and the second sub-layer 242.

An orthographic projection of the first lead layer 212 and the second lead layer 42 in the dam area 121 at least partially overlaps an orthographic projection of the first sub-layer 241 and the second sub-layer 242 in the dam area 121, thereby providing shielding in the dam area 121 by the first sub-layer 241 and the second sub-layer 242.

The first sub-layer 241 extends to the second sub-area 1222 and the dam area 121, so that a better shielding effect can be produced by the first sub-layer 241 and various power lines and signal lines in the function reuse layer 131 can be led out of the non-display area 12 through the first sub-layer 241.

The second sub-layer 242 extends to the first sub-area 1221, the second sub-area 1222, and the dam area 121, so that the shielding effect can be further improved.

Through such arrangement, the isolation structure layer 32 and the function reuse layer 131 are stacked on each other to completely cover the non-display area 12, so that signal crosstalk between the first lead layer 212 and the second lead layer 42 can be effectively shielded in the non-display area 12 at the bezel. Furthermore, the isolation structure layer 32, the first sub-layer 241, and the second sub-layer 242 are provided in the second sub-area 1222 to achieve three-layer shielding, the first sub-layer 241 and the second sub-layer 242 are provided in the dam area 121 to achieve two-layer shielding, and the dummy pixel structure layer 321 and the second sub-layer 242 are provided in the first sub-area 1221 to achieve two-layer shielding, so that the shielding effect is better.

The corresponding relationship between films in the display area 11 and the non-display area 12 has been illustrated in the above embodiments, so details are not described herein.

FIG. 14 and FIG. 15 mainly show an overlapping relationship of the first wire 25 in the non-display area 12. The first wire 25 includes a first-layer power wire 251 arranged in the same layer as the first sub-layer 241 and a second-layer power wire 252 arranged in the same layer as the second sub-layer 242. Orthographic projections of one part of the first-layer power wire 251 and the isolation structure layer 32 on the interlayer insulating layer 22 partially overlap, and the part of the first-layer power wire 251 is electrically connected with the isolation structure layer 32.

Orthographic projections of the second-layer power wire 252 and the other part of the first-layer power wire 251 on the interlayer insulating layer 22 partially overlap, and the second-layer power wire 252 is electrically connected with the other part of the first-layer power wire 251. The orthographic projections of the second-layer power wire 252 and the other part of the first-layer power wire 251 on the interlayer insulating layer 22 partially overlap in the dam area 121 and the first sub-area 1221, and the second-layer power wire 252 is electrically connected with the other part of the first-layer power wire 251 in the dam area 121 and the first sub-area 1221.

The first wire 25 includes a first power line and a second power line. The first power line is the other part of the first-layer power wire 251 and the second-layer power wire 252 in which the orthographic projections of the second-layer power wire 252 and the other part of the first-layer power wire 251 on the interlayer insulating layer 22 partially overlap, and the second-layer power wire 252 is electrically connected with the other part of the first-layer power wire 251, and the second power line is the part of the first-layer power wire 251 and the isolation structure layer 32 in which the orthographic projections of the part of the first-layer power wire 251 and the isolation structure layer 32 on the interlayer insulating layer 22 partially overlap, and the part of the first-layer power wire 251 is electrically connected with the isolation structure layer 32.

In some embodiments, the first power line is an ELVDD power line, the second power line is an ELVSS power line, and the ELVSS power line and the ELVDD power line are lines that supply power to the light-emitting layer 3 of the display panel 100.

Through such arrangement, the second-layer power wire 252 and the other part of the first-layer power wire 251 form the first power line, and the first power line and the second power line are arranged in different sub-layers, which can achieve separation and improve the shielding effect.

The display panel 100 provided in the embodiments of the present application can achieve separation of the first wire 25 and effectively shield signal crosstalk between the first lead layer 212 and the second lead layer 42.

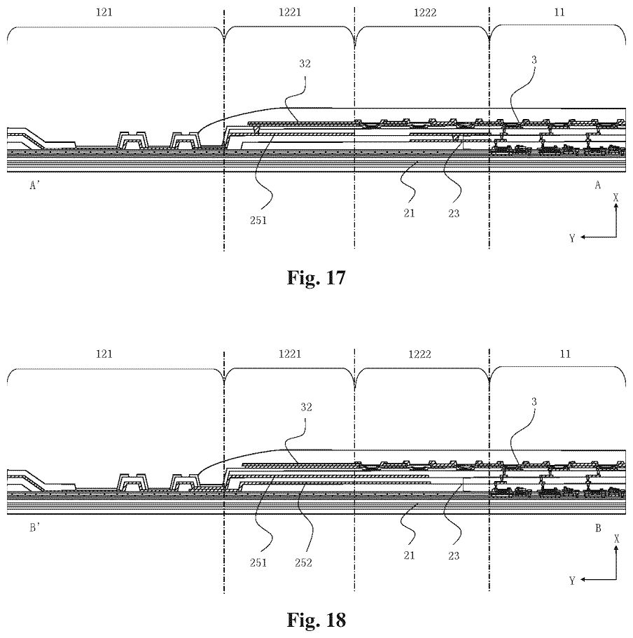

Referring to FIG. 16, FIG. 17, and FIG. 18, another embodiment of the present application provides a display panel 100.

FIG. 16 mainly shows a stacking relationship of the non-display area 12 and a corresponding same-layer relationship with the display area 11. The stacking relationship of the non-display area 12 will be described below.

The non-display area 12 includes a first lead layer 212, a second lead layer 42, and a functional layer 13, for which the functions and arrangement manners have been illustrated in the above embodiments, so details are not described herein.

The first sub-layer 241 extends to the first sub-area 1221, the second sub-area 1222, and the dam area 121, and the second sub-layer 242 extends to the second sub-area 1222.

An orthographic projection of the first lead layer 212 and the second lead layer 42 in the first sub-area 1221 at least partially overlaps an orthographic projection of the dummy pixel structure layer 321 and the first sub-layer 241 in the first sub-area 1221, thereby providing shielding in the first sub-area 1221 by the dummy pixel structure layer 321 and the first sub-layer 241.

An orthographic projection of the first lead layer 212 and the second lead layer 42 in the second sub-area 1222 at least partially overlaps an orthographic projection of the isolation material layer 322, the first sub-layer 241, and the second sub-layer 242 in the second sub-area 1222, thereby providing shielding in the second sub-area 1222 by the isolation material layer 322, the first sub-layer 241, and the second sub-layer 242.

An orthographic projection of the first lead layer 212 and the second lead layer 42 in the dam area 121 at least partially overlaps an orthographic projection of the first sub-layer 241 in the dam area 121, thereby providing shielding in the dam area 121 by the first sub-layer 241.

The first sub-layer 241 extends to the first sub-area 1221, the second sub-area 1222, and the dam area 121, so that a better shielding effect can be produced by the first sub-layer 241 and various power lines and signal lines in the function reuse layer 131 can be led out of the non-display area 12 through the first sub-layer 241.

The second sub-layer 242 extends to the second sub-area 1222, so that the shielding effect can be further improved.

Through such arrangement, the isolation structure layer 32 and the function reuse layer 131 are stacked on each other to completely cover the non-display area 12, so that signal crosstalk between the first lead layer 212 and the second lead layer 42 can be effectively shielded in the non-display area 12 at the bezel. Furthermore, the isolation structure layer 32, the first sub-layer 241, and the second sub-layer 242 are provided in the second sub-area 1222 to achieve three-layer shielding, the first sub-layer 241 and the dummy pixel structure layer 321 are provided in the first sub-area 1221 to achieve two-layer shielding, so that the shielding effect is improved.

The corresponding relationship between films in the display area 11 and the non-display area 12 has been illustrated in the above embodiments, so details are not described herein.

FIG. 17 and FIG. 18 mainly show an overlapping relationship of the first wire 25 in the non-display area 12. The first wire 25 includes a first-layer power wire 251 arranged in the same layer as the first sub-layer 241 and a second-layer power wire 252 arranged in the same layer as the second sub-layer 242. Orthographic projections of one part of the first-layer power wire 251 and the isolation structure layer 32 on the interlayer insulating layer 22 partially overlap, and the part of the first-layer power wire 251 is electrically connected with the isolation structure layer 32.

Orthographic projections of the second-layer power wire 252 and the other part of the first-layer power wire 251 on the interlayer insulating layer 22 partially overlap, and the second-layer power wire 252 is electrically connected with the other part of the first-layer power wire 251. The orthographic projection of the first-layer power wire 251 on the interlayer insulating layer 22 completely overlap the orthographic projection of the second-layer power wire 252 on the interlayer insulating layer 22, and the second-layer power wire 252 and the other part of the first-layer power wire 251 are electrically connected in the dam area 121 and the first sub-area 1221.

The first wire 25 includes a first power line and a second power line. The first power line is the other part of the first-layer power wire 251 and the second-layer power wire 252 in which the orthographic projections of the second-layer power wire 252 and the other part of the first-layer power wire 251 on the interlayer insulating layer 22 partially overlap, and the second-layer power wire 252 is electrically connected with the other part of the first-layer power wire 251, and the second power line is the part of the first-layer power wire 251 and the isolation structure layer 32 in which the orthographic projections of the part of the first-layer power wire 251 and the isolation structure layer 32 on the interlayer insulating layer 22 partially overlap, and the part of the first-layer power wire 251 is electrically connected with the isolation structure layer 32.

In some embodiments, the first power line is an ELVDD power line, the second power line is an ELVSS power line, and the ELVSS power line and the ELVDD power line are lines that supply power to the light-emitting layer 3 of the display panel 100.

Through such arrangement, the second-layer power wire 252 and the other part of the first-layer power wire 251 form the first power line, the first power line and the second power line are arranged in different sub-layers to achieve separation, and the first-layer power wire 251 completely covers the second-layer power wire 252, which can improve the shielding effect.

The display panel 100 provided in the embodiments of the present application can achieve separation of the first wire 25 and further effectively shield signal crosstalk between the first lead layer 212 and the second lead layer 42.

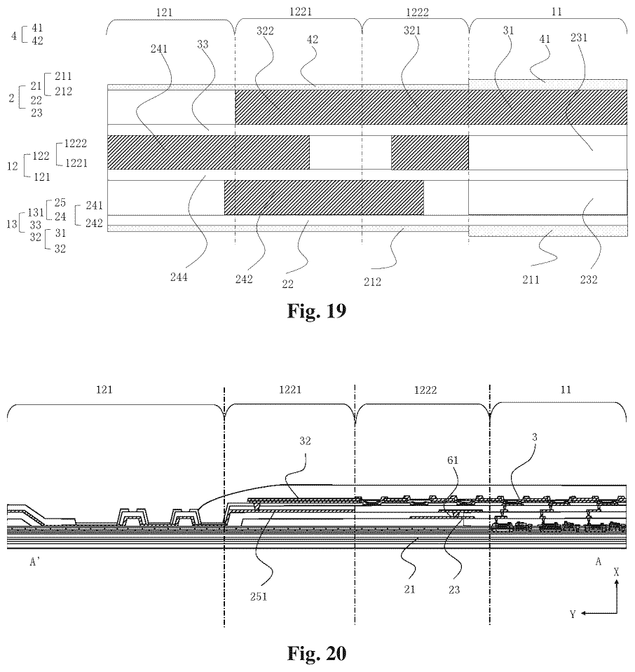

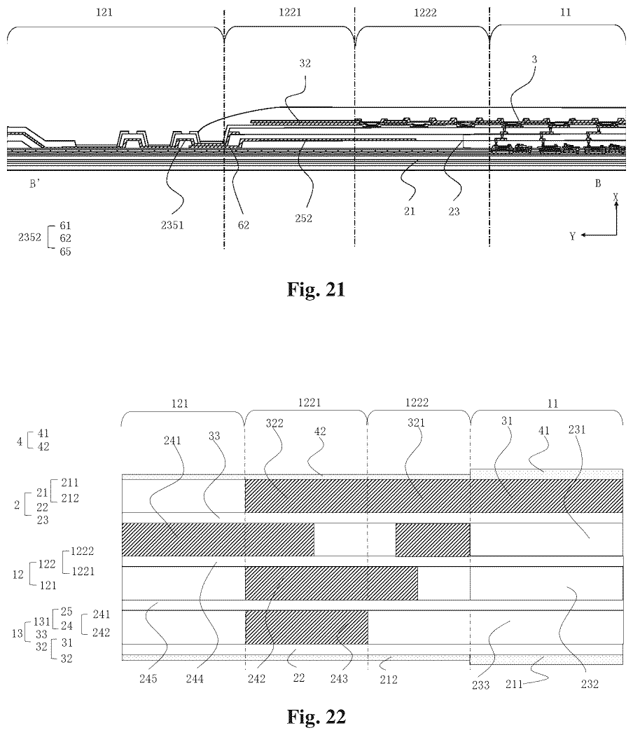

Referring to FIG. 19, FIG. 20, and FIG. 21, another embodiment of the present application provides a display panel 100.

FIG. 19 mainly shows a stacking relationship of the non-display area 12 and a corresponding same-layer relationship with the display area 11. The stacking relationship of the non-display area 12 will be described below.

The non-display area 12 includes a first lead layer 212, a second lead layer 42, and a functional layer 13, for which the functions and arrangement manners have been illustrated in the above embodiments, so details are not described herein.

The first sub-layer 241 extends to the second sub-area 1222 and the dam area 121, and the second sub-layer 242 extends to the second sub-area 1222.

An orthographic projection of the first lead layer 212 and the second lead layer 42 in the first sub-area 1221 at least partially overlaps an orthographic projection of the dummy pixel structure layer 321 in the first sub-area 1221, thereby providing shielding in the first sub-area 1221 by the dummy pixel structure layer 321.

An orthographic projection of the first lead layer 212 and the second lead layer 42 in the second sub-area 1222 at least partially overlaps an orthographic projection of the isolation material layer 322, the first sub-layer 241, and the second sub-layer 242 in the second sub-area 1222, thereby providing shielding in the second sub-area 1222 by the isolation material layer 322, the first sub-layer 241, and the second sub-layer 242.

An orthographic projection of the first lead layer 212 and the second lead layer 42 in the dam area 121 at least partially overlaps an orthographic projection of the first sub-layer 241 in the dam area 121, thereby providing shielding in the dam area 121 by the first sub-layer 241.

The first sub-layer 241 extends to the second sub-area 1222 and the dam area 121, so that a shielding effect can be produced by the first sub-layer 241 and various power lines and signal lines in the function reuse layer 131 can be led out of the non-display area 12 through the first sub-layer 241.

The second sub-layer 242 extends to the second sub-area 1222, so that the shielding effect can be further improved.

Through such arrangement, the isolation structure layer 32 and the function reuse layer 131 are stacked on each other to completely cover the non-display area 12, so that signal crosstalk between the first lead layer 212 and the second lead layer 42 can be effectively shielded in the non-display area 12 at the bezel. Furthermore, the isolation structure layer 32, the first sub-layer 241, and the second sub-layer 242 are provided in the second sub-area 1222 to achieve three-layer shielding, so that the shielding effect is maintained.

The corresponding relationship between films in the display area 11 and the non-display area 12 has been illustrated in the above embodiments, so details are not described herein.

FIG. 20 and FIG. 21 mainly show an overlapping relationship of the first wire 25 in the non-display area 12. The first wire 25 includes a first-layer power wire 251 arranged in the same layer as the first sub-layer 241 and a second-layer power wire 252 arranged in the same layer as the second sub-layer 242. Orthographic projections of one part of the first-layer power wire 251 and the isolation structure layer 32 on the interlayer insulating layer 22 partially overlap, and the part of the first-layer power wire 251 is electrically connected with the isolation structure layer 32.

Orthographic projections of the second-layer power wire 252 and the other part of the first-layer power wire 251 on the interlayer insulating layer 22 partially overlap, and the second-layer power wire 252 is electrically connected with the other part of the first-layer power wire 251. The second-layer power wire 252 includes a first line end 61, a second line end 62, and a first main section 65, the first line end 61 is connected to one side of the first main section 65, the second line end 62 is connected to the other side of the first main section 65, and the orthographic projections of the first-layer power wire 251 and the second-layer power wire 252 on the interlayer insulating layer 22 partially overlap only at the first line end 61 and the second line end 62, and the first-layer power wire 251 and the second-layer power wire 252 are electrically connected only at the first line end 61 and the second line end 62. Orthographic projections of the first line end 61 of the second-layer power wire 252 and the other part of the first-layer power wire 251 on the interlayer insulating layer 22 partially overlap in the dam area 121, and the first line end 61 of the second-layer power wire 252 and the other part of the first-layer power wire 251 are electrically connected in the dam area 121. Orthographic projections of the second line end 62 of the second-layer power wire 252 and the other part of the first-layer power wire 251 on the interlayer insulating layer 22 partially overlap in the first sub-area 1221, and the second line end 62 of the second-layer power wire 252 and the other part of the first-layer power wire 251 are electrically connected in the first sub-area 1221.

The first wire 25 includes a first power line and a second power line. The first power line is the other part of the first-layer power wire 251 and the second-layer power wire 252 in which the orthographic projections of the second-layer power wire 252 and the other part of the first-layer power wire 251 on the interlayer insulating layer 22 partially overlap, and the second-layer power wire 252 is electrically connected with the other part of the first-layer power wire 251, and the second power line is the part of the first-layer power wire 251 and the isolation structure layer 32 in which the orthographic projections of the part of the first-layer power wire 251 and the isolation structure layer 32 on the interlayer insulating layer 22 partially overlap, and the part of the first-layer power wire 251 is electrically connected with the isolation structure layer 32.

In some embodiments, the first power line is an ELVDD power line, the second power line is an ELVSS power line, and the ELVSS power line and the ELVDD power line are lines that supply power to the light-emitting layer 3 of the display panel 100.

Through such arrangement, the second-layer power wire 252 and the other part of the first-layer power wire 251 form the first power line, and the first power line and the second power line are arranged in different sub-layers to achieve separation. Only the first line end 61 and the second line end 62 of the second-layer power wire 252 are covered, which can maintain the shielding effect, and also reduce the weight and thickness of the display panel 100 and maintain effective overlapping.

The display panel 100 provided in the embodiments of the present application achieves separation of the first wire 25 and maintains the shielding effect, and can further reduce the weight and the thickness of the display panel 100 and maintain effective overlapping.

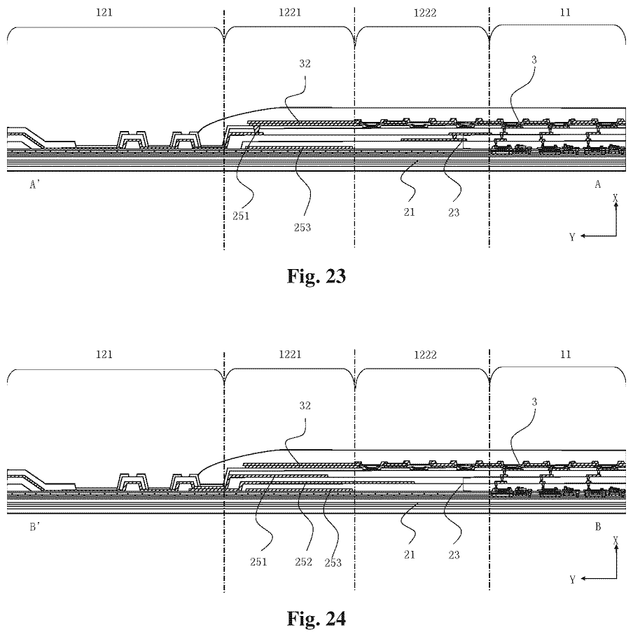

Referring to FIG. 22, FIG. 23, and FIG. 24, another embodiment of the present application provides a display panel 100.

FIG. 22 mainly shows a stacking relationship of the non-display area 12 and a corresponding same-layer relationship with the display area 11. The stacking relationship of the non-display area 12 will be described below.

The non-display area 12 includes a first lead layer 212, a second lead layer 42, and a functional layer 13, for which the functions and arrangement manners have been illustrated in the above embodiments, so details are not described herein.

The shielding layer 24 in the function reuse layer 131 further includes a third sub-layer 243 and a second wire insulating layer arranged along a direction opposite to the first direction X on a side of the second sub-layer 242 away from the first sub-layer 241, further improving the shielding effect.

The first sub-layer 241 extends to the second sub-area 1222 and the dam area 121, the second sub-layer 242 extends to the second sub-area 1222, and the third sub-layer 243 extends to the second sub-area 1222.

An orthographic projection of the first lead layer 212 and the second lead layer 42 in the first sub-area 1221 at least partially overlaps an orthographic projection of the dummy pixel structure layer 321 in the first sub-area 1221, thereby providing shielding in the first sub-area 1221 by the dummy pixel structure layer 321.

An orthographic projection of the first lead layer 212 and the second lead layer 42 in the second sub-area 1222 at least partially overlaps an orthographic projection of the isolation material layer 322, the first sub-layer 241, the second sub-layer 242, and the third sub-layer 243 in the second sub-area 1222, thereby providing shielding in the second sub-area 1222 by the isolation material layer 322, the first sub-layer 241, the second sub-layer 242, and the third sub-layer 243.

An orthographic projection of the first lead layer 212 and the second lead layer 42 in the dam area 121 at least partially overlaps an orthographic projection of the first sub-layer 241 in the dam area 121, thereby providing shielding in the dam area 121 by the first sub-layer 241.

The first sub-layer 241 extends to the second sub-area 1222 and the dam area 121, so that a shielding effect can be produced by the first sub-layer 241 and various power lines and signal lines in the function reuse layer 131 can be led out of the non-display area 12 through the first sub-layer 241.

The second sub-layer 242 extends to the second sub-area 1222, so that the shielding effect can be further improved.

The third sub-layer 243 extends to the second sub-area 1222, so that the shielding effect can be further improved.

Through such arrangement, the isolation structure layer 32 and the function reuse layer 131 are stacked on each other to completely cover the non-display area 12, so that signal crosstalk between the first lead layer 212 and the second lead layer 42 can be effectively shielded in the non-display area 12 at the bezel. Furthermore, the isolation structure layer 32, the first sub-layer 241, the second sub-layer 242, and the third sub-layer 243 are provided in the second sub-area 1222 to achieve four-layer shielding, so that the shielding effect is improved.

The wiring connection layer 23 further includes a third connection layer 233 arranged on a side of the second connection layer 232 away from the first connection layer 231, the third sub-layer 243 is arranged in the same layer as the third connection layer 233, and the second wire insulating layer 245 is arranged between the second sub-layer 242 and the third sub-layer 243.

Other corresponding relationships between films in the display area 11 and the non-display area 12 has been illustrated in the above embodiments, so details are not described herein.

FIG. 23 and FIG. 24 mainly show an overlapping relationship of the first wire 25 in the non-display area 12. The first wire 25 includes a first-layer power wire 251 arranged in the same layer as the first sub-layer 241, a second-layer power wire 252 arranged in the same layer as the second sub-layer 242, and a third-layer power wire 253 arranged in the same layer as the third sub-layer 243. Orthographic projections of one part of the first-layer power wire 251 and the isolation structure layer 32 on the interlayer insulating layer 22 partially overlap, and the part of the first-layer power wire 251 is electrically connected with the interlayer insulating layer 22.

Orthographic projections of the second-layer power wire 252 and the other part of the first-layer power wire 251 on the interlayer insulating layer 22 partially overlap, and the second-layer power wire 252 is electrically connected with the other part of the first-layer power wire 251. The second-layer power wire 252 includes a first line end 61, a second line end 62, and a first main section 65, the first line end 61 is connected to one side of the first main section 65, the second line end 62 is connected to the other side of the first main section 65, and the orthographic projections of the first-layer power wire 251 and the second-layer power wire 252 on the interlayer insulating layer 22 partially overlap only at the first line end 61 and the second line end 62, and the first-layer power wire 251 and the second-layer power wire 252 are electrically connected only at the first line end 61 and the second line end 62. Orthographic projections of the first line end 61 of the second-layer power wire 252 and the other part of the first-layer power wire 251 on the interlayer insulating layer 22 partially overlap in the dam area 121, and the first line end 61 of the second-layer power wire 252 and the other part of the first-layer power wire 251 are electrically connected in the dam area 121. The orthographic projections of the second line end 62 of the second-layer power wire 252 and the other part of the first-layer power wire 251 on the interlayer insulating layer 22 partially overlap in the first sub-area 1221, the second line end 62 of the second-layer power wire 252 and the other part of the first-layer power wire 251 and are electrically connected in the first sub-area 1221.

The first wire 25 includes a first power line and a second power line. The first power line is the other part of the first-layer power wire 251 and the second-layer power wire 252 in which the orthographic projections of the second-layer power wire 252 and the other part of the first-layer power wire 251 on the interlayer insulating layer 22 partially overlap, and the second-layer power wire 252 is electrically connected with the other part of the first-layer power wire 251, and the second power line is the part of the first-layer power wire 251 and the isolation structure layer 32 in which the orthographic projections of the part of the first-layer power wire 251 and the isolation structure layer 32 on the interlayer insulating layer 22 partially overlap, and the part of the first-layer power wire 251 is electrically connected with the interlayer insulating layer 22.

In some embodiments, the first power line is an ELVDD power line, the second power line is an ELVSS power line, and the ELVSS power line and the ELVDD power line are lines that supply power to the light-emitting layer 3 of the display panel 100.

Through such arrangement, the second-layer power wire 252 and the other part of the first-layer power wire 251 form the first power line, and the first power line and the second power line are arranged in different sub-layers to achieve separation. Only the first line end 61 and the second line end 62 of the second-layer power wire 252 are covered, which can maintain the shielding effect, and also reduce the weight and thickness of the display panel 100 and maintain effective overlapping. Through the addition of the third-layer power wire 253 arranged in the same layer as the third sub-layer 243, the shielding effect can be further improved.

The display panel 100 provided in the embodiments of the present application achieves separation of the first wire 25 and maintains the shielding effect, and can further improve the shielding effect.

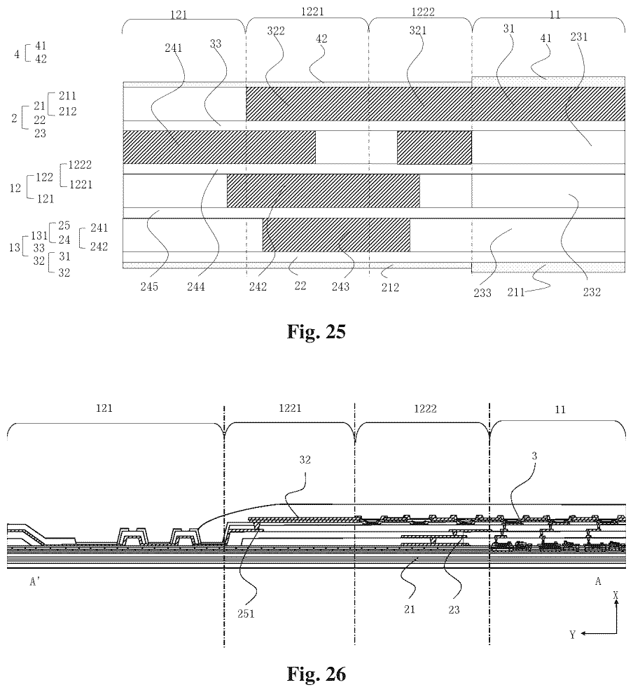

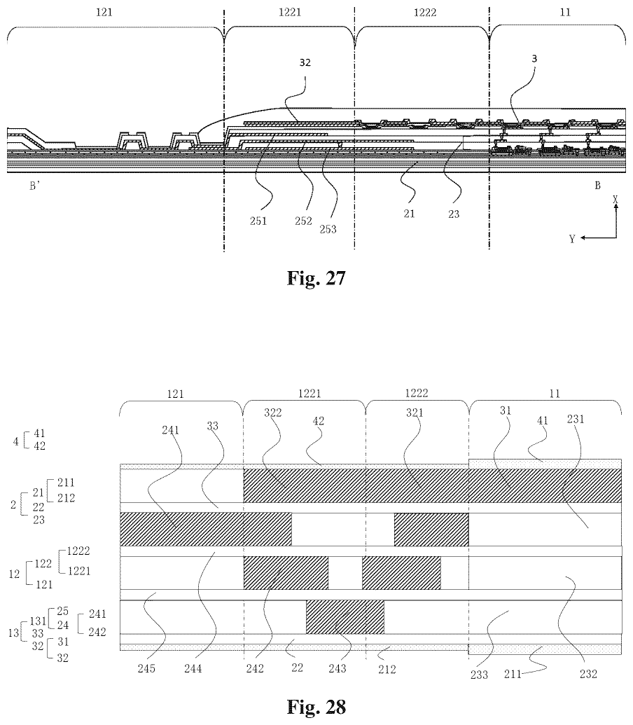

Referring to FIG. 25, FIG. 26, and FIG. 27, another embodiment of the present application provides a display panel 100.

FIG. 25 mainly shows a stacking relationship of the non-display area 12 and a corresponding same-layer relationship with the display area 11. The stacking relationship of the non-display area 12 will be described below.

The non-display area 12 includes a first lead layer 212, a second lead layer 42, and a functional layer 13, for which the functions and arrangement manners have been illustrated in the above embodiments, so details are not described herein.

The shielding layer 24 in the function reuse layer 131 further includes a third sub-layer 243 arranged along a direction opposite to the first direction on a side of the second sub-layer 242 away from the first sub-layer 241, further improving the shielding effect.

The first sub-layer 241 extends to the second sub-area 1222 and the dam area 121, the second sub-layer 242 extends to the second sub-area 1222, and the third sub-layer 243 extends to the second sub-area 1222.

An orthographic projection of the first lead layer 212 and the second lead layer 42 in the first sub-area 1221 at least partially overlaps an orthographic projection of the dummy pixel structure layer 321 in the first sub-area 1221, thereby providing shielding in the first sub-area 1221 by the dummy pixel structure layer 321.

An orthographic projection of the first lead layer 212 and the second lead layer 42 in the second sub-area 1222 at least partially overlaps an orthographic projection of the isolation material layer 322, the first sub-layer 241, and the second sub-layer 242 in the second sub-area 1222, thereby providing shielding in the second sub-area 1222 by the isolation material layer 322, the first sub-layer 241, and the second sub-layer 242.

An orthographic projection of the first lead layer 212 and the second lead layer 42 in the dam area 121 at least partially overlaps an orthographic projection of the first sub-layer 241 in the dam area 121, thereby providing shielding in the dam area 121 by the first sub-layer 241.

The first sub-layer 241 extends to the second sub-area 1222 and the dam area 121, so that a shielding effect can be produced by the first sub-layer 241 and various power lines and signal lines in the function reuse layer 131 can be led out of the non-display area 12 through the first sub-layer 241.

The second sub-layer 242 extends to the second sub-area 1222, so that the shielding effect can be further improved.

The third sub-layer 243 extends to the second sub-area 1222, so that the shielding effect can be further improved.

Through such arrangement, the isolation structure layer 32 and the function reuse layer 131 are stacked on each other to completely cover the non-display area 12, so that signal crosstalk between the first lead layer 212 and the second lead layer 42 can be effectively shielded in the non-display area 12 at the bezel. Furthermore, the isolation structure layer 32, the first sub-layer 241, the second sub-layer 242, and the third sub-layer 243 are provided in the second sub-area 1222 to achieve four-layer shielding, so that the shielding effect is improved.

The corresponding relationship between films in the display area 11 and the non-display area 12 has been illustrated in the above embodiments, so details are not described herein.

FIG. 26 and FIG. 27 mainly show an overlapping relationship of the first wire 25 in the non-display area 12. The first wire 25 includes a first-layer power wire 251 arranged in the same layer as the first sub-layer 241, a second-layer power wire 252 arranged in the same layer as the second sub-layer 242, and a third-layer power wire 253 arranged in the same layer as the third sub-layer 243. Orthographic projections of one part of the first-layer power wire 251 and the isolation structure layer 32 on the interlayer insulating layer 22 partially overlap, and the part of the first-layer power wire 251 is electrically connected with the isolation structure layer 32.

Orthographic projections of the second-layer power wire 252 and the other part of the first-layer power wire 251 on the interlayer insulating layer 22 partially overlap, and the second-layer power wire 252 is electrically connected with the other part of the first-layer power wire 251. The second-layer power wire 252 includes a first line end 61, a second line end 62, and a first main section 65, the first line end 61 is connected to one side of the first main section 65, the second line end 62 is connected to the other side of the first main section 65, and the orthographic projections of the first-layer power wire 251 and the second-layer power wire 252 on the interlayer insulating layer 22 partially overlap only at the first line end 61 and the second line end 62, and the first-layer power wire 251 and the second-layer power wire 252 are electrically connected only at the first line end 61 and the second line end 62. Orthographic projections of the first line end 61 of the second-layer power wire 252 and the other part of the first-layer power wire 251 on the interlayer insulating layer 22 partially overlap in the dam area 121, and he first line end 61 of the second-layer power wire 252 and the other part of the first-layer power wire 251 are electrically connected in the dam area 121. Orthographic projections of the second line end 62 of the second-layer power wire 252 and the other part of the first-layer power wire 251 on the interlayer insulating layer 22 partially overlap in the first sub-area 1221, and the second line end 62 of the second-layer power wire 252 and the other part of the first-layer power wire 251 are electrically connected in the first sub-area 1221.

The orthographic projection of the second-layer power wire 252 on the interlayer insulating layer 22 completely covers the orthographic projection of the third-layer power wire 253 on the interlayer insulating layer 22, and the third-layer power wire 253 is electrically connected to the second-layer power wire 252 in the first sub-area 1221 and the second sub-area 1222.

The first wire 25 includes a first power line and a second power line. The first power line is the other part of the first-layer power wire 251, the second-layer power wire 252, and the third-layer power wire 253, in which the orthographic projections of the other part of the first-layer power wire 251, the second-layer power wire 252, and the third-layer power wire 253 on the interlayer insulating layer 22 overlap, and the other part of the first-layer power wire 251, the second-layer power wire 252, and the third-layer power wire 253 are electrically connected, and the second power line is the part of the first-layer power wire 251 and the isolation structure layer 32, in which the orthographic projections of the part of the first-layer power wire 251 and the isolation structure layer 32 on the interlayer insulating layer 22 partially overlap, and the part of the first-layer power wire 251 is electrically connected with the isolation structure layer 32.

In some embodiments, the first power line is an ELVDD power line, the second power line is an ELVSS power line, and the ELVSS power line and the ELVDD power line are lines that supply power to the light-emitting layer 3 of the display panel 100.

Through such arrangement, the third-layer power wire 253, the second-layer power wire 252, and the other part of the first-layer power wire 251 form the first power line, and the first power line and the second power line are arranged in different sub-layers to achieve separation. Only the first line end 61 and the second line end 62 of the second-layer power wire 252 are covered, which can maintain the shielding effect, and also reduce the weight and thickness of the display panel 100 and maintain effective overlapping. The second-layer power wire 252 completely covers the third-layer power wire 253, so that the shielding effect can be further improved.

The display panel 100 provided in the embodiments of the present application achieves separation of the first wire 25 and maintains the shielding effect, and can further improve the shielding effect.

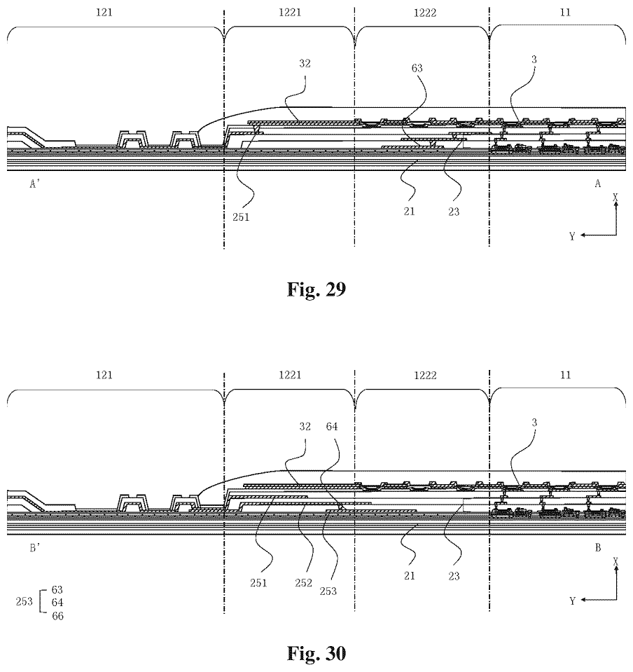

Referring to FIG. 28, FIG. 29, and FIG. 30, another embodiment of the present application provides a display panel 100.

FIG. 28 mainly shows a stacking relationship of the non-display area 12 and a corresponding same-layer relationship with the display area 11. The stacking relationship of the non-display area 12 will be described below.

The non-display area 12 includes a first lead layer 212, a second lead layer 42, and a functional layer 13, for which the functions and arrangement manners have been illustrated in the above embodiments, so details are not described herein.

The shielding layer 24 in the function reuse layer 131 further includes a third sub-layer 243 arranged along a direction opposite to the first direction on a side of the second sub-layer 242 away from the first sub-layer 241, further improving the shielding effect.

The first sub-layer 241 extends to the second sub-area 1222 and the dam area 121, the second sub-layer 242 extends to the second sub-area 1222, and the third sub-layer 243 extends to the second sub-area 1222.

An orthographic projection of the first lead layer 212 and the second lead layer 42 in the first sub-area 1221 at least partially overlaps an orthographic projection of the dummy pixel structure layer 321 in the first sub-area 1221, thereby providing shielding in the first sub-area 1221 by the dummy pixel structure layer 321.

An orthographic projection of the first lead layer 212 and the second lead layer 42 in the second sub-area 1222 at least partially overlaps an orthographic projection of the isolation material layer 322, the first sub-layer 241, and the second sub-layer 242 in the second sub-area 1222, thereby providing shielding in the second sub-area 1222 by the isolation material layer 322, the first sub-layer 241, and the second sub-layer 242.

An orthographic projection of the first lead layer 212 and the second lead layer 42 in the dam area 121 at least partially overlaps an orthographic projection of the first sub-layer 241 in the dam area 121, thereby providing shielding in the dam area 121 by the first sub-layer 241.

The first sub-layer 241 extends to the second sub-area 1222 and the dam area 121, so that a shielding effect can be produced by the first sub-layer 241 and various power lines and signal lines in the function reuse layer 131 can be led out of the non-display area 12 through the first sub-layer 241.

The second sub-layer 242 shields the second sub-area 1222, so that the shielding effect can be further improved.

The third sub-layer 243 shields the second sub-area 1222, so that the shielding effect can be further improved.

Through such arrangement, the isolation structure layer 32 and the function reuse layer 131 are stacked on each other to completely cover the non-display area 12, so that signal crosstalk between the first lead layer 212 and the second lead layer 42 can be effectively shielded in the non-display area 12 at the bezel. Furthermore, the isolation structure layer 32, the first sub-layer 241, the second sub-layer 242, and the third sub-layer 243 are provided in the second sub-area 1222 to achieve four-layer shielding, so that the shielding effect is improved.

The corresponding relationship between films in the display area 11 and the non-display area 12 has been illustrated in the above embodiments, so details are not described herein.

FIG. 29 and FIG. 30 mainly show an overlapping relationship of the first wire 25 in the non-display area 12. The first wire 25 includes a first-layer power wire 251 arranged in the same layer as the first sub-layer 241, a second-layer power wire 252 arranged in the same layer as the second sub-layer 242, and a third-layer power wire 253 arranged in the same layer as the third sub-layer 243. Orthographic projections of one part of the first-layer power wire 251 and the isolation structure layer 32 on the interlayer insulating layer 22 partially overlap, and the part of the first-layer power wire 251 is electrically connected with the isolation structure layer 32.

Orthographic projections of the second-layer power wire 252 and the other part of the first-layer power wire 251 on the interlayer insulating layer 22 partially overlap, and the second-layer power wire 252 is electrically connected with the other part of the first-layer power wire 251. The second-layer power wire 252 includes a first line end 61, a second line end 62, and a first main section 65, the first line end 61 is connected to one side of the first main section 65, the second line end 62 is connected to the other side of the first main section 65, and the orthographic projections of the first-layer power wire 251 and the second-layer power wire 252 on the interlayer insulating layer 22 partially overlap only at the first line end 61 and the second line end 62, and the first-layer power wire 251 and the second-layer power wire 252 are electrically connected only at the first line end 61 and the second line end 62. Orthographic projections of the first line end 61 of the second-layer power wire 252 and the other part of the first-layer power wire 251 on the interlayer insulating layer 22 partially overlap in the dam area 121, and the first line end 61 of the second-layer power wire 252 and the other part of the first-layer power wire 251 are electrically connected in the dam area 121. Orthographic projections of the second line end 62 of the second-layer power wire 252 and the other part of the first-layer power wire 251 on the interlayer insulating layer 22 partially overlap in the first sub-area 1221, and the second line end 62 of the second-layer power wire 252 and the other part of the first-layer power wire 251 are electrically connected in the first sub-area 1221.

Orthographic projections of the third-layer power wire 253 and the second-layer power wire 252 on the interlayer insulating layer 22 partially overlap, and the third-layer power wire 253 and the second-layer power wire 252 are electrically connected. The third-layer power wire 253 includes a third line end 63, a fourth line end 64, and a second main section 66, the third line end 63 is connected to one side of the second main section 66, the fourth line end 64 is connected to the other side of the second main section 66, and the orthographic projections of the third-layer power wire 253 and the second-layer power wire 252 on the interlayer insulating layer 22 partially overlap only at the third line end 63 and the fourth line end 64, and the third-layer power wire 253 and the second-layer power wire 252 are electrically connected only at the third line end 63 and the fourth line end 64. Orthographic projections of the third line end 63 of the third-layer power wire 253 and the second-layer power wire 252 on the interlayer insulating layer 22 partially overlap in the second sub-area 1222, and the third line end 63 of the third-layer power wire 253 and the second-layer power wire 252 are electrically connected in the second sub-area 1222. Orthographic projections of the fourth line end 64 of the third-layer power wire 253 and the second-layer power wire 252 on the interlayer insulating layer 22 partially overlap in the first sub-area 1221, and the fourth line end 64 of the third-layer power wire 253 and the second-layer power wire 252 are electrically connected in the first sub-area 1221.

The first wire 25 includes a first power line and a second power line. The first power line is the other part of the first-layer power wire 251, the second-layer power wire 252, and the third-layer power wire 253, in which the orthographic projections of the other part of the first-layer power wire 251, the second-layer power wire 252, and the third-layer power wire 253 on the interlayer insulating layer 22 overlap, and the other part of the first-layer power wire 251, the second-layer power wire 252, and the third-layer power wire 253 are electrically connected, and the second power line is the part of the first-layer power wire 251 and the isolation structure layer 32, in which the orthographic projections of the part of the first-layer power wire 251 and the isolation structure layer 32 on the interlayer insulating layer 22 partially overlap, and the part of the first-layer power wire 251 is electrically connected with the isolation structure layer 32.

In some embodiments, the first power line is an ELVDD power line, the second power line is an ELVSS power line, and the ELVSS power line and the ELVDD power line are lines that supply power to the light-emitting layer 3 of the display panel 100.

Through such arrangement, the third-layer power wire 253, the second-layer power wire 252, and the other part of the first-layer power wire 251 form the first power line, and the first power line and the second power line are arranged in different sub-layers to achieve separation. The other part of the first-layer power wire 251 covers only the first line end 61 and the second line end 62 of the second-layer power wire 252, and the second-layer power wire 252 covers only the third line end 63 and the fourth line end 64, which can maintain the shielding effect, and also reduce the weight and thickness of the display panel 100 and maintain effective overlapping.

The display panel 100 provided in the embodiments of the present application achieves separation of the first wire 25 and maintains the shielding effect, and can further reduce the weight and the thickness of the display panel 100.

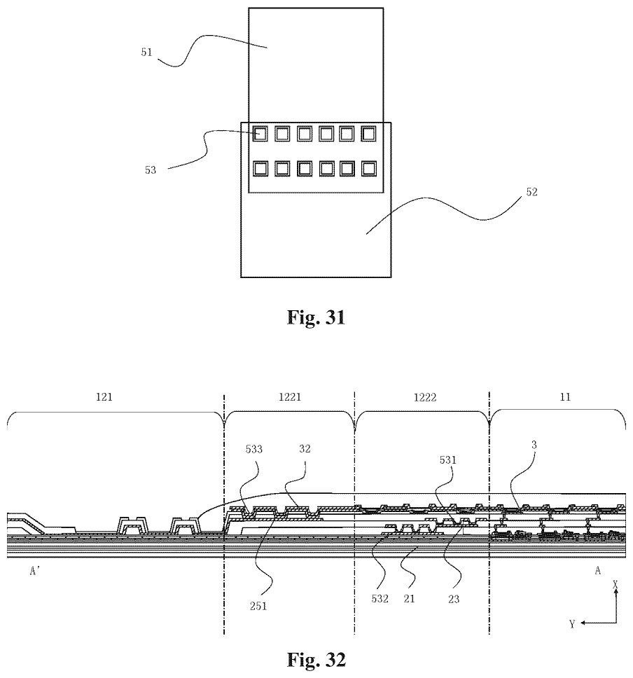

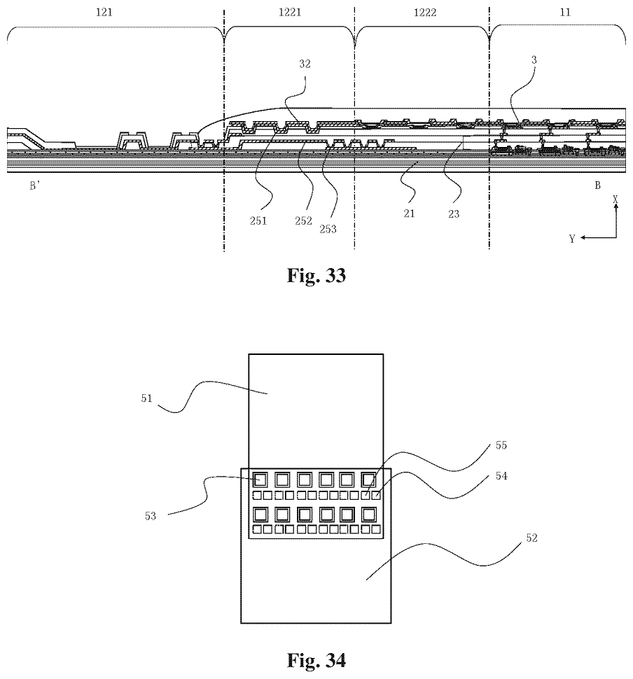

Referring to FIG. 31, FIG. 32, and FIG. 33, another embodiment of the present application provides a display panel 100.

Referring to FIG. 31, the first film 51 and the second film 52 are connected by an insulating layer located between the first film 51 and the second film 52 and provided with via holes 53 arranged in an array and covering an overlapping zone of the first film 51 and the second film 52, so that the first film 51 and the second film 52 overlap and are electrically connected through the via holes 53.

Referring to FIG. 32 and FIG. 33, in some embodiments, the first film 51 is the first-layer power wire 251, the second film 52 is the second-layer power wire 252, and the insulating layer is the first wire insulating layer 244.

The first wire insulating layer 244 is provided with first via holes 531 distributed in an array and covering an overlapping zone of the orthographic projections of the first-layer power wire 251 and the second-layer power wire 252 on the interlayer insulating layer 22, and the first-layer power wire 251 is electrically connected to the second-layer power wire 252 through the first via holes 531.

In some embodiments, the first film 51 is the second-layer power wire 252, the second film 52 is the third-layer power wire 253, and the insulating layer is the second wire insulating layer 245.

The second-layer power wire 252 is provided with second via holes 532 distributed in an array and covering an overlapping zone of the orthographic projections of the second-layer power wire 252 and the third-layer power wire 253 on the interlayer insulating layer 22, and the second-layer power wire 252 is electrically connected to the third-layer power wire 253 through the second via holes 532.

In some embodiments, the first film 51 is the isolation material layer 322, the second film 52 is the first-layer power wire 251, and the insulating layer is the substrate insulating layer 33.

The isolation material layer 322 is provided with third via holes 533 distributed in an array and covering an overlapping zone of the orthographic projections of the isolation material layer 322 and the first-layer power wire 251 on the interlayer insulating layer 22, and the isolation material layer 322 is electrically connected to the first-layer power wire 251 through the third via holes 533.

In the display panel 100 provided in the embodiments of the present application, the insulating layer between the films covers the overlapping zone of the orthographic projections of the entire films through a plurality of via holes distributed in an array, which effectively maintains an overlapping effect and can also prevent waste and make full use of the overlapping zone of the orthographic projections of two films, so that shielding is achieved through an overlapping relationship and the overlapping zone can further improve the shielding effect by using a connecting portion.

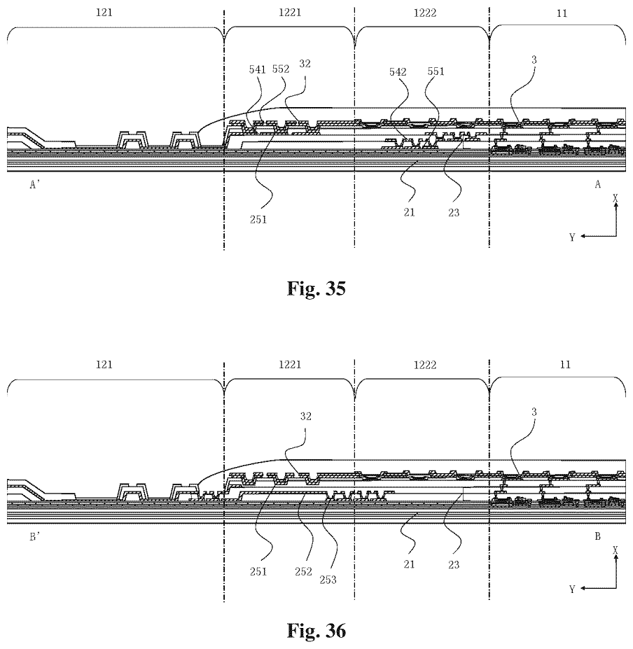

Referring to FIG. 34, FIG. 35, and FIG. 36, another embodiment of the present application provides a display panel 100.

Referring to FIG. 34, the first film 51 and the second film 52 are further provided with a first film ventilation hole 54 and a second film ventilation hole 55, and orthographic projections of the first film ventilation hole 54 and the second film ventilation hole 55 are spaced apart in the overlapping zone of the first film 51 and the second film 52.

Furthermore, the orthographic projections of the first film ventilation hole 54, the second film ventilation hole 55, and the via holes 53 are spaced apart.

Referring to FIG. 35 and FIG. 36, in some embodiments, the first film 51 is the first-layer power wire 251, and the second film 52 is the second-layer power wire 252.

The first-layer power wire 251 is provided with a first ventilation hole 541, the second-layer power wire 252 is provided with a second ventilation hole 542, orthographic projections of the first ventilation hole 541 and the second ventilation hole 542 on the interlayer insulating layer 22 are spaced apart in an overlapping zone of the orthographic projections of the first-layer power wire 251 and the second-layer power wire 252 on the interlayer insulating layer 22, and the orthographic projections of the first ventilation hole 541, the second ventilation hole 542, and the first via hole 531 on the interlayer insulating layer 22 are spaced apart.

In some embodiments, the first film 51 is the second-layer power wire 252, and the second film 52 is the third-layer power wire 253.

The second-layer power wire 252 is provided with a second ventilation hole 542, the third-layer power wire 253 is provided with a third ventilation hole 551, orthographic projections of the second ventilation hole 542 and the third ventilation hole 551 on the interlayer insulating layer 22 are spaced apart in an overlapping zone of the second-layer power wire 252 and the third-layer power wire 253, and the orthographic projections of the second ventilation hole 542, the third ventilation hole 551, and the second via hole 532 on the interlayer insulating layer 22 are spaced apart.

In some embodiments, the first film 51 is the first-layer power wire 251, and the second film 52 is the isolation material layer 322.

The first-layer power wire 251 is provided with a first ventilation hole 541, the isolation material layer 322 is provided with a fourth ventilation hole 552, orthographic projections of the first ventilation hole 541 and the fourth ventilation hole 552 on the interlayer insulating layer 22 are spaced apart in an overlapping zone of the first-layer power wire 251 and the isolation material layer 322, and the orthographic projections of the first ventilation hole 541, the fourth ventilation hole 552, and the third via hole 533 on the interlayer insulating layer 22 are spaced apart.

In the display panel 100 provided in the embodiments of the present application, the arrangement of the ventilation holes can prevent covering of the entire metal wiring film by an organic material, and lack of a structure to release and exhaust the gas generated by the organic material during subsequent processes such as hot pressing and high-temperature treatment, and the display panel 100 provided in the embodiments of the present application can release pressure on the metal wiring film without affecting the overlapping and shielding effects.

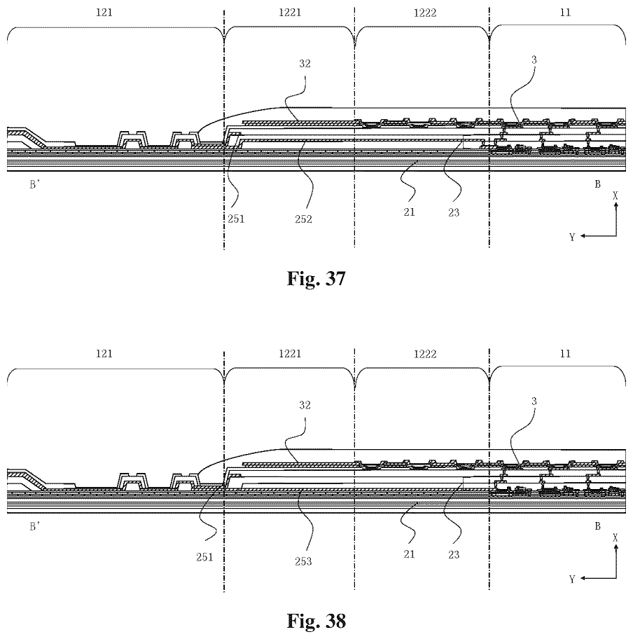

In addition, referring to FIG. 37, optionally, in some embodiments, the orthographic projection of the second-layer power wire 252 of the first power line on the interlayer insulating layer 22 and the orthographic projection of the first-layer power wire 251 of the first power line on the interlayer insulating layer 22 partially overlap in the dam area 121, and the first-layer power wire 251 and the second-layer power wire 252 are electrically connected.

In the display panel provided in the embodiments of the present application, by directly leading the first power line ELVDD of the display panel out through the second-layer power wire 252, complexity of a wiring structure is reduced and reliability is improved.

The first power line may alternatively be arranged at one end of a boundary of the display area 11 in such a manner that ELVDD signal lines of each column of pixels are directly connected, then directly led out to the dam area 121 through the second-layer power wire 252, and are electrically connected to the first-layer power wire 251.

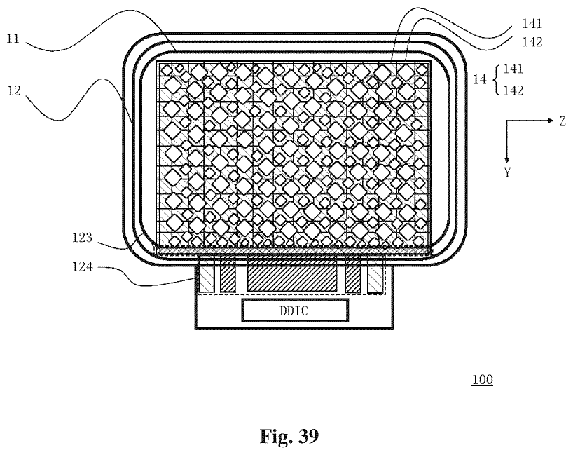

In addition, referring to FIG. 38, optionally, in some embodiments, the first power line includes only a part of the first-layer power wire 251 and the third-layer power wire 253, the orthographic projection of the first-layer power wire 251 on the interlayer insulating layer 22 and the orthographic projection of the third-layer power wire 253 on the interlayer insulating layer 22 partially overlap in the dam area 121, and the first-layer power wire 251 and the third-layer power wire 253 are electrically connected.

In the display panel 100 provided in the embodiments of the present application, by directly leading the first power line ELVDD of the display panel 100 out through the third-layer power wire 253, complexity of a wiring structure is reduced and reliability is improved.

The first power line may alternatively be arranged at one end of a boundary of the display area 11 in such a manner that ELVDD signal lines of each column of pixels are directly connected, then directly led out to the dam area 121 through the third-layer power wire 253, and are electrically connected to the first-layer power wire 251.

In yet another aspect, referring to FIG. 2 and FIG. 39, an embodiment of the present application further provides a display panel 100 including a display area 11 and a non-display area 12, and the non-display area 12 includes a first lead layer 212, a second lead layer 42, and a power wire distribution layer 14.

The second lead layer 42 is stacked along a first direction X on one side of the first lead layer 212. The power wire distribution layer 14 is arranged between the first lead layer 212 and the second lead layer 42. The first wire includes a first distribution layer 141 and a second distribution layer 142. Orthographic projections of the first distribution layer 141 and the second distribution layer 142 on the first lead layer 212 at least partially overlap.

In the display panel 100 provided in the embodiments of the present application, through the stacking of the first distribution layer 141 and the second distribution layer 142 between the first lead layer 212 and the second lead layer 42, signal crosstalk between the first lead layer 212 and the second lead layer 42 can be shielded.

In some embodiments, the non-display area includes a first zone 123 and a second zone 124 continuously arranged along a second direction Y, in the first zone 123, the orthographic projection of the first distribution layer 141 on the first lead layer 212 is within the orthographic projection of the second distribution layer 142 on the first lead layer 212, and in the second zone 124, the orthographic projections of the first distribution layer 141 and the second distribution layer 142 on the first lead layer 212 are spaced apart.

In the display panel 100 provided in the embodiments of the present application, the first distribution layer 141 and the second distribution layer 142 are separated and spaced apart in the second zone 124, so that wiring signal crosstalk in the first distribution layer 141 and the second distribution layer 142 can be prevented.

In some optional embodiments, in the first zone 123, the first distribution layer 141 and the second distribution layer 142 are continuously arranged along a third direction Z.

In such embodiments, in the display panel 100 provided in the embodiments of the present application, the first distribution layer 141 and the second distribution layer 142 may be arranged in a strip-like shape in the first zone 123, and through the continuous arrangement, the first distribution layer 141 and the second distribution layer 142 connect power signal lines of each column of pixels and then lead the power signal lines out.

In some optional embodiments, in the second zone 124, the first distribution layer 141 and the second distribution layer 142 are arranged at intervals along the third direction Z, and the first distribution layer 141 is arranged on two sides of the second distribution layer 142.

In such embodiments, in the display panel 100 provided in the embodiments of the present application, the first distribution layer 141 and the second distribution layer 142 are wired separately in the second zone 124, preventing signal crosstalk.

In some optional embodiments, the first distribution layer 141 includes part of the first sub-layer 241 and the isolation structure layer 32 stacked along the first direction X, and orthographic projections of the isolation structure layer 32 and the part of the first sub-layer 241 in the non-display area 12 at least partially overlap and the isolation structure layer and the part of the first sub-layer are electrically connected.

In such embodiments, in the display panel 100 provided in the embodiments of the present application, the first distribution layer 141 is configured as a structure in which the first sub-layer 241 and the isolation structure layer 32 overlap, to achieve separation of power wires.

In some embodiments, the second distribution layer 142 includes the other part of the first sub-layer 241.

In such embodiments, in the display panel 100 provided in the embodiments of the present application, the second distribution layer 142 is configured as the other part the first sub-layer 241, to achieve separation of power wires.

In another aspect, an embodiment of the present application further provides a display device, including the display panel 100 in any one of the above embodiments. Since the display device provided in the embodiments of the present application includes the display panel 100 in any one of the above embodiments, the display device provided in the embodiments in the second aspect of the present application has the beneficial effects of the display panel 100 in any one of the embodiments in the first aspect. Details are not described herein again in this embodiment.

The display device in the embodiments of the present application includes, but is not limited to, a mobile phone, a personal digital assistant (PDA), a tablet computer, an e-book, a television, an access control, a smart fixed phone, a console, and other devices with a display function.

Although the present application has been described with reference to the preferred embodiments, various modifications may be made thereto and components may be replaced with equivalents without departing from the scope of the present application. In particular, the technical features mentioned in various embodiments can be combined in any manner provided that there is no structural conflict. The present application is not limited to the specific embodiments disclosed herein, but includes all technical solutions falling into the protection scope of the claims.

What is claimed is:

1. A display panel comprising a display area and a non-display area, the non-display area comprises:
a first lead layer;
a second lead layer stacked along a first direction on one side of the first lead layer; and
a functional layer arranged between the first lead layer and the second lead layer, the functional layer comprising a function reuse layer, the function reuse layer comprising a shielding layer and a first wire, the shielding layer comprising a first sub-layer, and the first wire being arranged in the same layer as the first sub-layer.

2. The display panel of claim 1, wherein the functional layer further comprises an isolation structure layer stacked along the first direction on a side of the function layer away from the first lead layer;
the non-display area comprises a first area and a dam area continuously arranged along a second direction, the isolation structure layer extends to a first area, and the first sub-layer extends to the dam area and at least part of the first area;
an orthographic projection of the first lead layer and the second lead layer in the first area at least partially overlaps an orthographic projection of the isolation structure layer and the first sub-layer in the first area, and an orthographic projection of the first lead layer and the second lead layer in the dam area at least partially overlaps an orthographic projection of the first sub-layer in the dam area;
the first area comprises a first sub-area and a second sub-area continuously arranged along the second direction, the isolation structure layer comprises a dummy pixel structure layer and an isolation material layer continuously arranged along the second direction, the dummy pixel structure layer correspondingly extending to the first sub-area, the isolation material layer correspondingly extending to the second sub-area, and the first sub-layer extends to the dam area and at least the second sub-area; and
an orthographic projection of the first lead layer and the second lead layer in the first sub-area at least partially overlaps an orthographic projection of the dummy pixel structure layer in the first sub-area, an orthographic projection of the first lead layer and the second lead layer in the second sub-area at least partially overlaps an orthographic projection of the isolation material layer and the first sub-layer in the second sub-area, and an orthographic projection of the first lead layer and the second lead layer in the dam area at least partially overlaps an orthographic projection of the first sub-layer in the dam area.

3. The display panel of claim 2, wherein
the shielding layer further comprises a second sub-layer arranged along a direction opposite to the first direction on a side of the first sub-layer away from the isolation structure layer, the second sub-layer extends at least partially within the first area;
an orthographic projection of the first lead layer and the second lead layer in the first area at least partially overlaps an orthographic projection of the second sub-layer in the first area;
the shielding layer further comprises a third sub-layer arranged along the direction opposite to the first direction on a side of the second sub-layer away from the first sub-layer, the third sub-layer extends at least partially within the second sub-area; and
the orthographic projection of the first lead layer and the second lead layer in the second sub-area at least partially overlaps an orthographic projection of the isolation material layer, the first sub-layer, the second sub-layer, and the third sub-layer in the second sub-area.

4. The display panel of claim 3, wherein the display area comprises a first signal unit layer, a first connection layer, a light-emitting unit layer, and a second signal unit layer stacked along the first direction;
the first signal unit layer is arranged in the same layer as the first lead layer, the second signal unit layer is arranged in the same layer as the second lead layer, the first connection layer is arranged in the same layer as the first sub-layer, the light-emitting unit layer comprises a plurality of light-emitting units, the isolation structure layer encloses and forms a plurality of isolation openings, and the light-emitting units are exposed from the isolation openings; and
the display area further comprises a second connection layer, the second connection layer is arranged in the same layer as the second sub-layer.

5. A display panel comprising a display area and a non-display area, the display panel comprising an array substrate and a second signal line layer stacked along a first direction, the array substrate comprising a first signal line layer, an interlayer insulating layer, and a wiring connection layer stacked along the first direction, and the interlayer insulating layer being arranged between the first signal line layer and the wiring connection layer;
the wiring connection layer comprises:
a first connection layer located in the display area; and
a shielding layer and a first wire at least partially located in the non-display area, an orthographic projection of the shielding layer on the interlayer insulating layer at least partially overlaps an orthographic projection of a first lead layer of the first signal line layer and a second lead layer of the second signal line layer on the interlayer insulating layer, the shielding layer comprises a first sub-layer, the first sub-layer is arranged in the same layer as the first connection layer, and at least part of the first wire is arranged in the same layer as the first sub-layer.

6. The display panel of claim 5, wherein the non-display area comprises a first area and a dam area continuously arranged along a second direction, the wiring connection layer further comprises a second connection layer, the second connection layer is arranged on a side of the first connection layer close to the first signal line layer, the shielding layer further comprises a first wire insulating layer and a second sub-layer, the second sub-layer is arranged in the same layer as the second connection layer, the first wire insulating layer is arranged between the first sub-layer and the second sub-layer, and the first wire is arranged in the same layer as at least one of the first sub-layer and the second sub-layer; and
the first wire comprises a first-layer power wire arranged in the same layer as the first sub-layer and a second-layer power wire arranged in the same layer as the second sub-layer, and orthographic projections of the first-layer power wire and the second-layer power wire on the interlayer insulating layer at least partially overlap and the first-layer power wire and the second-layer power wire are electrically connected;
the orthographic projection of the second-layer power wire on the interlayer insulating layer is located within the orthographic projection of the first-layer power wire on the interlayer insulating layer; and
the second-layer power wire comprises a first line end, a second line end, and a first main section, the first line end is connected to one side of the first main section, the second line end is connected to the other side of the first main section, and the orthographic projections of the first-layer power wire and the second-layer power wire on the interlayer insulating layer overlap at the first line end and the second line end and the first-layer power wire and the second-layer power wire are electrically connected at the first line end and the second line end.

7. The display panel of claim 6, wherein the first wire insulating layer is provided with at least one first via hole, and the first-layer power wire is electrically connected to the second-layer power wire through the first via hole; or
the first wire insulating layer is provided with a plurality of first via holes, the first via holes are distributed in an array; and
an arrangement zone of the first via holes covers an overlapping zone of the orthographic projections of the first-layer power wire and the second-layer power wire on the interlayer insulating layer.

8. The display panel of claim 6, wherein the wiring connection layer further comprises a third connection layer arranged on a side of the second connection layer away from the first connection layer; and
the shielding layer further comprises a second wire insulating layer and a third sub-layer, the third sub-layer is arranged in the same layer as the third connection layer, the second wire insulating layer is arranged between the second sub-layer and the third sub-layer, and the first wire is arranged in the same layer as at least one of the first sub-layer, the second sub-layer, or the third sub-layer;
the first wire comprises a first-layer power wire arranged in the same layer as the first sub-layer, a second-layer power wire arranged in the same layer as the second sub-layer, and a third-layer power wire arranged in the same layer as the third sub-layer, and orthographic projections of the first-layer power wire, the second-layer power wire, and the third-layer power wire on the interlayer insulating layer at least partially overlap and the first-layer power wire, the second-layer power wire, and the third-layer power are electrically connected;
the orthographic projection of the third-layer power wire on the interlayer insulating layer is located within the orthographic projection of the second-layer power wire on the interlayer insulating layer; and
the third-layer power wire comprises a third line end, a fourth line end, and a second main section, the third line end is connected to one side of the second main section, the fourth line end is connected to the other side of the second main section, and the orthographic projections of the second-layer power wire and the third-layer power wire on the interlayer insulating layer overlap only at the third line end and the fourth line end and the second-layer power wire and the third-layer power wire are electrically connected only at the third line end and the fourth line end.

9. The display panel of claim 8, wherein
the second wire insulating layer is provided with at least one second via hole, and the second-layer power wire is electrically connected to the third-layer power wire through the second via hole; or
the second wire insulating layer is provided with a plurality of second via holes, the second via holes are distributed in an array; and
an arrangement zone of the second via holes covers an overlapping zone of the orthographic projections of the second-layer power wire and the third-layer power wire on the interlayer insulating layer.

10. The display panel of claim 6, wherein the display panel further comprises a light-emitting layer arranged between the array substrate and the second signal line layer, the light-emitting layer comprises a substrate insulating layer, a light-emitting unit layer, and an isolation structure layer, the substrate insulating layer is arranged between the isolation structure layer and the array substrate, the light-emitting unit layer comprises a plurality of light-emitting units, the isolation structure layer encloses and forms a plurality of isolation openings, and the light-emitting units are exposed from the isolation openings;
orthographic projections of the first-layer power wire and the isolation structure layer on the interlayer insulating layer at least partially overlap and the first-layer power wire and the isolation structure are electrically connected; or
the isolation structure layer further comprises a dummy pixel structure layer and an isolation material layer continuously arranged along a second direction, and orthographic projections of the first-layer power wire and the isolation material layer on the interlayer insulating layer at least partially overlap and the first-layer power wire and the isolation material layer are electrically connected; or
the light-emitting layer further comprises an electrode layer located between the array substrate and the light-emitting unit layer, the electrode layer comprises pixel electrodes located in the display area and electrode shielding sections at least partially located in the non-display area, and an orthographic projection of the electrode shielding section on the interlayer insulating layer at least partially overlaps the orthographic projection of the first lead layer of the first signal line layer and the second lead layer of the second signal line layer on the interlayer insulating layer; or
the first sub-layer is further provided with a first aperture, the electrode shielding section is further provided with a second aperture, and an orthographic projection of the first aperture on the interlayer insulating layer is located within the orthographic projection of the electrode shielding section on the interlayer insulating layer; or
an orthographic projection of the second aperture on the interlayer insulating layer is located within an orthographic projection of the first sub-layer on the interlayer insulating layer; or
the first sub-layer is insulated from the first wire; or
the first sub-layer is electrically connected to the electrode layer; or
the first sub-layer is electrically connected to the electrode shielding section; or
the substrate insulating layer comprises a planarization layer located between the electrode shielding section and the first sub-layer, the planarization layer is provided with a first via hole, and the electrode shielding section and the first sub-layer are electrically connected through the first via hole; or
the first sub-layer comprises a plurality of first sub-sections arranged at intervals, the first aperture is located in the first sub-sections; or
the orthographic projection of the second aperture on the interlayer insulating layer is located within an orthographic projection of the first sub-section on the interlayer insulating layer; or
a minimum distance between an edge of the orthographic projection of the second aperture on the interlayer insulating layer and an edge of an orthographic projection of a corresponding first sub-section on the interlayer insulating layer is greater than or equal to 5μm; or
an edge of the orthographic projection of the first sub-section on the interlayer insulating layer has a first side and a second side opposite to each other, a distance between the edge of the orthographic projection of the second aperture on the interlayer insulating layer and the first side is a first distance, a distance between the edge of the orthographic projection of the second aperture on the interlayer insulating layer and the second side is a second distance, and the first distance is equal to the second distance; or
the first distance is greater than or equal to 5 μm; or
the second distance is greater than or equal to 5 μm; or
a distance between adjacent second apertures is less than or equal to 80 μm; or
the first sub-section extends along the second direction, and the first aperture and the second aperture are staggered along the second direction; or
one second aperture is arranged between two first apertures adjacent along the second direction; or
a distance between the second aperture and an adjacent first aperture is greater than or equal to 5 μm; or
the first area comprises a first sub-area and a second sub-area, the first sub-area is located on a side of the second sub-area away from the display area, the display panel comprises a shielding assembly, the shielding assembly comprises the first sub-layer and the electrode shielding section, and an orthographic projection of the first sub-area on the interlayer insulating layer is located within an orthographic projection of the shielding assembly on the interlayer insulating layer; or
the isolation structure layer is located in the display area and the second sub-area, and an orthographic projection of the isolation structure layer on the interlayer insulating layer and the orthographic projection of the electrode shielding section on the interlayer insulating layer overlaps in the second sub-area; or
the orthographic projection of the shielding assembly on the interlayer insulating layer and the orthographic projection of the isolation structure layer on the interlayer insulating layer overlaps to form an overlapping zone, and a minimum width of the overlapping zone along a direction from the non-display area to the display area is greater than or equal to 5 μm; or
the non-display area comprises a straight edge area and an arcuate corner area located on two sides of the straight edge area along a third direction, the straight edge area is located on one side of the display area along the second direction, and the shielding assembly is located in the straight edge area and the arcuate corner area; or
the light-emitting unit layer further comprises dummy units located in the non-display area, the dummy units are located on a side of dummy electrodes away from the interlayer insulating layer, and a number of the dummy units within the arcuate corner area is greater than a number of the dummy units in the straight edge area.

11. The display panel of claim 10, wherein
the substrate insulating layer is provided with at least one third via hole, and the isolation material layer is electrically connected to the first-layer power wire through the third via hole;
the substrate insulating layer is provided with a plurality of third via holes, the third via holes are distributed in an array; and
the substrate insulating layer is provided with a plurality of third via holes, and an arrangement zone of the third via holes covers an overlapping zone of the orthographic projections of the isolation material layer and the first-layer power wire on the interlayer insulating layer.

12. The display panel of claim 7, wherein the first-layer power wire is further provided with a first ventilation hole, and the second-layer power wire is further provided with a second ventilation hole;
an orthographic projection of the first ventilation hole on the interlayer insulating layer and an orthographic projection of the second ventilation hole on the interlayer insulating layer are spaced apart in an overlapping zone of the first-layer power wire and the second-layer power wire; and
the orthographic projections of the first ventilation hole, the second ventilation hole, and the first via hole on the interlayer insulating layer are spaced apart.

13. The display panel of claim 9, wherein the second-layer power wire is further provided with a second ventilation hole, and the third-layer power wire is further provided with a third ventilation hole;
an orthographic projection of the second ventilation hole on the interlayer insulating layer and an orthographic projection of the third ventilation hole on the interlayer insulating layer are spaced apart in an overlapping zone of the second-layer power wire and the third-layer power wire; and
the orthographic projections of the second ventilation hole, the third ventilation hole, and the second via hole on the interlayer insulating layer are spaced apart.

14. The display panel of claim 11, wherein the first-layer power wire is further provided with a first ventilation hole, and the isolation material layer is further provided with a fourth ventilation hole; and
an orthographic projection of the first ventilation hole on the interlayer insulating layer and an orthographic projection of the fourth ventilation hole on the interlayer insulating layer are spaced apart in an overlapping zone of the first-layer power wire and the isolation material layer; and
the orthographic projections of the first ventilation hole, the fourth ventilation hole, and the third via hole on the interlayer insulating layer are spaced apart.

15. The display panel of claim 6, wherein the first wire comprises a first power line and a second power line, the first power line comprises a part of the first-layer power wire and the second-layer power wire, wherein orthographic projections of the part of the first-layer power wire and the second-layer power wire on the interlayer insulating layer partially overlap, and the part of the first-layer power wire is electrically connected with the second-layer power wire;
an orthographic projection of the second-layer power wire of the first power line on the interlayer insulating layer and an orthographic projection of the first-layer power wire of the first power line on the interlayer insulating layer partially overlap in the dam area, and the first-layer power wire and the second-layer power wire are electrically connected; and
the first power line is an electroluminscent voltage drain (ELVDD) power line, and the second power line is an electroluminscent voltage source (ELVSS) power line.

16. The display panel of claim 8, wherein the first wire comprises a first power line and a second power line, the first power line comprises a part of the first-layer power wire, the second-layer power wire, and the third-layer power wire, wherein orthographic projections of the part of the first-layer power wire, the second-layer power wire, and the third-layer power wire on the interlayer insulating layer partially overlap, and the part of the first-layer power wire, the second-layer power wire, and the third-layer power wire are electrically connected;
the first power line comprises only part of the first-layer power wire and the third-layer power wire, the orthographic projection of the first-layer power wire on the interlayer insulating layer and the orthographic projection of the third-layer power wire on the interlayer insulating layer partially overlap in the dam area, and the first-layer power wire and the third-layer power wire are electrically connected; and
the first power line is an ELVDD power line, and the second power line is an ELVSS power line.

17. The display panel of claim 10, wherein the first wire comprises a first power line and a second power line, the second power line comprises a part of the first-layer power wire and the isolation structure layer, wherein orthographic projections of the part of the first-layer power wire and the isolation structure layer on the interlayer insulating layer partially overlap, and the part of the first-layer power wire is electrically connected with the isolation structure layer; and
the first power line is an ELVDD power line, and the second power line is an ELVSS power line.

18. A display panel comprising a display area and a non-display area, the non-display area comprises:
a first lead layer;
a second lead layer stacked along a first direction on one side of the first lead layer; and
a power wire distribution layer arranged between the first lead layer and the second lead layer, the power wire distribution layer comprising a first distribution layer and a second distribution layer, and orthographic projections of the first distribution layer and the second distribution layer on the first lead layer at least partially overlapping.

19. The display panel of claim 18, wherein the non-display area comprises a first zone and a second zone continuously arranged along a second direction, in the first zone, the orthographic projection of the first distribution layer on the first lead layer is within the orthographic projection of the second distribution layer on the first lead layer, and in the second zone, the orthographic projections of the first distribution layer and the second distribution layer on the first lead layer are spaced apart;
in the first zone, the first distribution layer and the second distribution layer are continuously arranged along a third direction;
in the second zone, the first distribution layer and the second distribution layer are arranged at intervals along the third direction, and the first distribution layer is arranged on two sides of the second distribution layer;
the first distribution layer comprises a part of a first sub-layer and an isolation structure layer stacked along the first direction, and orthographic projections of the isolation structure layer and the part of the first sub-layer in the non-display area at least partially overlap and the isolation structure layer is electrically connected with the part of the first sub-layer; and
the second distribution layer comprises the other part of the first sub-layer.

20. A display device, comprising the display panel of claim 1.
